(19) United States
(12) Patent Application Publication
(10) Pub. No.: US 2026/0371527 A1
(43) Pub. Date: Nov. 19, 2026

(54) COMPUTER COOLING SYSTEM WITH FREE COOLING

(71) Applicant: Tyco Fire & Security GmbH, Neuhausen am Rheinfall (CH)

(72) Inventors: Bryson Lee Sheaffer, Mechanicsburg, PA (US); Thomas P. Carter, Olney, MD (US)

(21) Appl. No.: 19/676,578

(22) Filed: May 13, 2026

Related U.S. Application Data
(60) Provisional application No. 63/805,915, filed on May 14, 2025.

(51) Int. Cl. H05K 7/20

(52) U.S. Cl. CPC H05K 7/20327; H05K 7/20318; H05K 7/20354; H05K 7/20818

(57) ABSTRACT

A computer cooling system includes a mechanical cooling system having a working fluid circuit configured to circulate a working fluid, a free cooling system having a free cooling circuit configured to circulate a cooling fluid, a first heat exchange interface disposed along the working fluid circuit, where the first heat exchange interface is configured to place the working fluid in a first heat exchange relationship with a computer component, and an accumulator disposed along the working fluid circuit and configured to receive the working fluid from the first heat exchange interface, where the accumulator at least partially defines a second heat exchange interface configured to place the working fluid in a second heat exchange relationship with the cooling fluid.

### CROSS-REFERENCE TO RELATED APPLICATIONS

This application claims priority to and the benefit of U.S. Provisional Patent Application No. 63/805,915, entitled “COMPUTER COOLING SYSTEM WITH FREE COOLING,” filed on May 14, 2025, which is hereby incorporated by reference in its entirety for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Heating, ventilation, air conditioning, and refrigeration (HVAC&R) systems, such as chiller systems (e.g., vapor compression systems), utilize a working fluid (e.g., a refrigerant) that changes phases between vapor, liquid, and combinations thereof in response to exposure to different temperatures and pressures within components of the chiller system. HVAC&R systems may include a compressor for circulating a working fluid (e.g., refrigerant) along a working fluid circuit and through heat exchangers of the HVAC&R system. For example, the HVAC&R system may include a first heat exchanger configured to receive the working fluid and a conditioning fluid to place the working fluid in the heat exchange relationship with the conditioning fluid. The conditioning fluid may be directed from the first heat exchanger to other equipment, such as air handlers, to condition other fluids, such as air or water. The HVAC&R system may also include a second heat exchanger configured to receive the working fluid and a cooling fluid to place the working fluid in the heat exchange relationship with the cooling fluid. In some embodiments, the cooling fluid may be water. Alternatively, the cooling fluid may be another fluid, such as air. Unfortunately, some HVAC&R system configurations are susceptible to various drawbacks, such as limited heat transfer efficiency, incompatibility with certain heating or cooling loads, and so forth.

Further to the points above, data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant to the racks to draw heat from the heat-generating equipment or use a combination of air cooling and liquid cooling. As data centers expand to support the rapid growth of cloud computing, artificial intelligence, and other modern applications having high computing loads and power densities, data centers demand effective, energy-efficient cooling solutions that serve these applications while mitigating environmental impact.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a computer cooling system includes a mechanical cooling system having a working fluid circuit configured to circulate a working fluid, a free cooling system having a free cooling circuit configured to circulate a cooling fluid, a first heat exchange interface disposed along the working fluid circuit, where the first heat exchange interface is configured to place the working fluid in a first heat exchange relationship with a computer component, and an accumulator disposed along the working fluid circuit and configured to receive the working fluid from the first heat exchange interface, where the accumulator at least partially defines a second heat exchange interface configured to place the working fluid in a second heat exchange relationship with the cooling fluid.

A computer cooling system may include a mechanical cooling system having a working fluid circuit configured to circulate a working fluid, a free cooling system having a free cooling circuit configured to circulate a cooling fluid, a first heat exchange interface disposed along the working fluid circuit, where the heat exchange interface is configured to place the working fluid in a heat exchange relationship with a computer chip, and a second heat exchange interface configured to place the working fluid in a heat exchange relationship with the cooling fluid.

In another embodiment, a computer cooling system includes a mechanical cooling system having a working fluid circuit configured to circulate a working fluid, a compressor disposed along the working fluid circuit, and a first pump disposed along the working fluid circuit. The computer cooling system further includes a free cooling system having a free cooling circuit and a second pump disposed along the free cooling circuit, where the second pump is configured to circulate a cooling fluid along the free cooling circuit, and a heat exchange interface disposed along the working fluid circuit, where the heat exchange interface is configured to place the working fluid in a heat exchange relationship with a computer component. The computer cooling system further includes an accumulator disposed along the working fluid circuit, wherein the accumulator is configured to separate the working fluid into liquid working fluid and vapor working fluid, and a control system configured to drive operation of the compressor to draw the vapor working fluid from the accumulator in a mechanical cooling mode of the computer cooling system, and suspend operation of the compressor and initiate operation of the first pump to draw the liquid working fluid from the accumulator in a free cooling mode of the computer cooling system.

In another embodiment, an accumulator for a computer cooling system that is configured to operate in a mechanical cooling mode and a free cooling mode includes a shell defining an interior volume configured to receive a working fluid from a heat exchange interface of the computer cooling system in both the mechanical cooling mode and the free cooling mode. The shell includes an upper portion and a lower portion, the accumulator is configured to separate the working fluid into vapor working fluid and liquid working fluid, the lower portion defines a reservoir configured to collect the liquid working fluid, and at least one flow channel extends through the interior volume of the shell. The at least one flow channel is disposed along a free cooling circuit and is configured to circulate a cooling fluid therethrough during the free cooling mode to place the cooling fluid in a heat exchange relationship with the working fluid within the accumulator. The accumulator further includes a first outlet disposed at a bottom of the shell and configured to enable the liquid working fluid to exit the shell during the free cooling mode via a pump disposed along a free cooling portion of a working fluid circuit, and a conduit extending at least partially through the upper portion of the shell. The conduit includes one or more openings configured to receive the vapor working fluid from within the shell and a second outlet configured to direct the vapor working fluid along a mechanical cooling portion of the working fluid circuit to a compressor of the computer cooling system during the mechanical cooling mode.

Various embodiments relate to an HVAC&R system for cooling computer electronics (e.g., a cooling system for a data center, etc.) where a fluid circuit (e.g., working fluid circuit) extends between a compressor, condenser, and a heat exchanger coupled to the computing electronics.

The HVAC&R system may include a compressor configured to compress a refrigerant (e.g., working fluid), a condenser configured to receive the refrigerant from the condenser and place the refrigerant in a heat exchange relationship with a cooling fluid, and a distribution network configured to direct the refrigerant from the condenser to a heat exchanger coupled to computing electronics within a server rack and direct the refrigerant from the heat exchanger to the compressor.

In any of the embodiments disclosed herein:

The condenser may be an air-cooled condenser. The condenser may be remotely located from the compressor. The condenser may be a dry cooler.

The compressor may be an oil-less compressor.

The heat exchanger may be configured to provide single phase or two-phase heat exchange with respect to the refrigerant as it passes through the heat exchanger. The heat exchanger may be a plate heat exchanger coupled to a surface of a computer chip. In some embodiments, the heat exchanger may be a cold plate.

The HVAC&R system may further include a free cooling to loop having a pump and a free cooling condenser configured to provide cooling to computer electronics without use of a compressor.

The HVAC&R system may include a compressor configured to compress a refrigerant, an air-cooled condenser configured to receive refrigerant from the condenser and place the refrigerant in a heat exchange relationship with a cooling fluid, and a distribution network configured to direct the refrigerant from the condenser to a heat exchanger coupled to computing electronics within a server rack and to direct the refrigerant from the heat exchanger to the compressor.

A cooling system for a data center may include a mechanical cooling loop having a first condenser, and a free cooling loop having a second condenser. The mechanical cooling loop may direct refrigerant from a compressor to one or more computer server racks. In one embodiment, the first and second condensers are cooled in series via a common airflow. In other embodiments the first and second condensers are cooled in parallel via separate air flows.

A cooling system for a data center may include a mechanical cooling loop and a free cooling loop. The mechanical cooling loop may include a magnetic bearing compressor (e.g., an oil-less compressor) and an air-cooled condenser. The free cooling loop may include a pump, an accumulator, and a dry cooler. The mechanical cooling loop may circulate a refrigerant through the magnetic bearing compressor, the air-cooled condenser, and one or more heat exchangers located at a server rack of the data center. The refrigerant may provide for two-phase heat exchange with computing electronics at the server rack.

A cooling system for a data center includes a mechanical cooling loop and a free cooling loop. The mechanical cooling loop circulates a two-phase refrigerant to a heat exchanger coupled to computer electronics. The free cooling loop circulates a liquid coolant between a pump and a dry cooler. The free cooling loop may be in a heat exchange relationship with the mechanical cooling loop.

A cooling system for a data center may include a mechanical cooling loop and a free cooling loop. The mechanical cooling loop may circulate a two-phase refrigerant to a computer enclosure having computer electronics disposed therein for immersion cooling of the computer electronics. The free cooling loop may circulate a liquid coolant between a pump and a dry cooler. The free cooling loop may be in a heat exchange relationship with the mechanical cooling loop.

A cooling system for a data center may include (a) a mechanical cooling circuit configured to direct fluid along a first fluid path including (i) a pump or compressor; (ii) a separator including a first heat exchanger; and (iii) a second heat exchanger coupled to computing electronics, and (b) a second circuit configured to direct a coolant fluid along a second fluid path including (i) a free cooling pump; (ii) the separator; and (iii) a dry cooler.

A cooling system for rejecting heat from computer servers of a data center may include a free cooling circuit and a mechanical cooling circuit. In a first configuration, the mechanical cooling circuit may reject heat via an air-cooled condenser. In a second configuration, the mechanical cooling circuit may reject heat via an accumulator or separator having a heat exchanger. In the second configuration, the free cooling circuit may absorb heat from the mechanical cooling circuit at the accumulator or separator and rejects the heat via a dry cooler.

A method of cooling computer servers within server racks of a data center may include circulating a two-phase refrigerant in a mechanical cooling loop and circulating a coolant liquid in a free cooling loop, transferring heat from the computer servers to the mechanical cooling loop, and transferring heat from the mechanical cooling loop to the free cooling loop. The mechanical cooling loop and the free cooling loop, in some embodiments, reject heat to an ambient environment via a common air flow of cooling air.

A method of cooling computer servers in a data center may include, in a first configuration, rejecting heat from the computer servers via an air-cooled condenser using a mechanical cooling circuit, and in a second configuration, rejecting heat from the computer servers to a free cooling circuit via the mechanical cooling circuit. The mechanical cooling circuit and the free cooling circuit, in some embodiments, reject heat to an ambient environment via a common air flow of cooling air.

A method of cooling computer electronics may include directing a refrigerant along a fluid path from a compressor, to an air-cooled condenser, to a cooling plate coupled to a computer chip of a server, to an accumulator or separator, and back to the compressor. The method, in some embodiments, further includes directing a coolant fluid through a pump, to the accumulator or separator, to a dry cooler, and back to the pump.

In some embodiments, a controller or processor (e.g., a processing circuit, processing circuitry) controls a cooling system (e.g., any of the cooling systems disclosed herein) configured to cool electronics components of a data center. The control system may be further configured to implement any of the method steps described herein. A computer-readable medium may include instructions that, when executed by the controller, are configured to implement the systems and/or methods of any of the embodiments disclosed herein.

In one or more of the embodiments disclosed herein, a data center cooling system may include a chiller configured as a water-cooled chiller that is in fluid communication with a cooling tower or similar structure for rejection of heat to an ambient environment.

In some embodiments, a controller controls a cooling system (e.g., any of the cooling systems disclosed herein) configured to cool electronics components of a data center. The control system may be further configured to implement any of the method steps described herein. A computer-readable medium may include instructions that when executed by the controller are configured to implement the systems and/or methods of any of the embodiments disclosed herein.

### BRIEF DESCRIPTION OF THE DRAWINGS

Various aspects of this disclosure may be better understood upon reading the following detailed description and upon reference to the drawings in which:

FIG. 1 is a perspective view of an embodiment of a data center room including racks served by a data center cooling system, in accordance with an aspect of the present disclosure;

FIG. 2 is a block diagram of an embodiment of a data center cooling system, such as the data center cooling system of FIG. 1, in accordance with an aspect of the present disclosure;

FIG. 3 is a block diagram of an embodiment of a rack of a data center room, such as the data center room of FIG. 1, in greater detail, in accordance with an aspect of the present disclosure;

FIG. 4 is a perspective view of an embodiment of a server tray which can be installed in one or more racks of a data center room, such as the data center room of FIG. 1, in accordance with an aspect of the present disclosure;

FIG. 5 is a block diagram of an embodiment of a liquid cooling circuit which can be used in a data center cooling system, such as the data center cooling system of FIG. 1, in accordance with an aspect of the present disclosure;

FIG. 6 is a block diagram of an embodiment of an air-cooling circuit which can be used in a data center cooling system, such as the data center cooling system of FIG. 1, in accordance with an aspect of the present disclosure;

FIG. 7 is a schematic of an embodiment of an HVAC&R system including a chiller system configured to provide cooling to electronic equipment, in accordance with an aspect of the present disclosure;

FIG. 8 is a schematic of an embodiment of an HVAC&R system including a chiller system configured to provide cooling to electronic equipment, in accordance with an aspect of the present disclosure;

FIG. 9 is a schematic diagram of an embodiment of a computer cooling system including a vapor compression system and a free cooling system, in accordance with an aspect of the present disclosure;

FIG. 10 is a schematic diagram of an embodiment of a computer cooling system including a vapor compression system and a free cooling system, in accordance with an aspect of the present disclosure; and

FIG. 11 is a schematic diagram of an embodiment of an accumulator for a computer cooling system having a vapor compression system and a free cooling system, in accordance with an aspect of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/- 5%, within +/- 4%, within +/- 3%, within +/- 2%, within +/- 1%, or even closer, of the given value. Similarly, when a given feature is described as being “substantially parallel” to another feature, “generally perpendicular” to another feature, and so forth, this is intended to convey that the given feature is within +/- 5%, within +/- 4%, within +/- 3%, within +/- 2%, within +/- 1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

As used herein, an HVAC&R system may include any number of components configured to enable regulation of one or more parameters related to climate characteristics, such as temperature, humidity, air flow, pressure, air quality, and so forth. For example, an “HVAC&R system” as used herein may be defined as a system configured to perform operations including one or more of heating, cooling, ventilation, dehumidification, pressurization, refrigeration, filtration, or any combination thereof. Indeed, certain HVAC&R systems incorporating the present techniques may be configured to perform certain operations (e.g., cooling) but not others (e.g., heating). Components or parts of an “HVAC&R system” may include, but are not limited to, all, some of, or individual parts such as a heat exchanger, a fluid flow control device, such as a valve, a sensor configured to detect a climate characteristic or operating parameter, a filter, a control device configured to regulate operation of an HVAC&R system component, a component configured to enable regulation of one or more climate characteristics, or a combination thereof. The embodiments described herein may be utilized in a variety of applications to control climate characteristics, such as residential, commercial, industrial, transportation, or other applications where climate control is desired.

A heating, ventilation, air conditioning, and/or refrigeration (HVAC&R) system (e.g., chiller system) may be implemented to thermally regulate a space within a building, home, or other suitable structure. HVAC&R systems may also be utilized to thermally regulate systems and/or components that demand thermal conditioning (e.g., providing cooling / heat rejection to components within a facility, such as a data center). In general, HVAC&R systems include a vapor compression system (e.g., vapor compression circuit) that transfers thermal energy between a working fluid (e.g., refrigerant) and a fluid to be conditioned, such as water, air, or another suitable fluid. The vapor compression system may include one or more heat exchangers, such as a condenser and an evaporator, that are fluidly coupled to one another via a working fluid circuit (e.g., refrigerant circuit, one or more conduits). The vapor compression system may also include a compressor configured to circulate the working fluid through the working fluid circuit and thereby enable the transfer of thermal energy between the condenser and the evaporator and respective fluids directed through the condenser and the evaporator.

In some applications, the HVAC&R system may be or include a chiller system configured to condition a conditioning fluid (e.g., water) that is directed to downstream equipment, such as air handlers, computer equipment, heat exchangers, and/or other components configured to utilize the conditioning fluid to cool a conditioned space, another device or component (e.g., computer system, computer server, electronic equipment), or both. To this end, the chiller system may include an evaporator configured to transfer heat from the conditioning fluid to a working fluid circulated through the chiller system. The chiller system may also include a condenser configured to transfer heat from the working fluid to a cooling fluid. In some applications, the cooling fluid may be water (e.g., water-cooled chiller). Alternatively, the cooling fluid may be air (e.g., air-cooled chiller). In yet further implementations, combinations of air and water may be used as the cooling fluid for the chiller system.

In some implementations, HVAC&R systems, such as chiller systems, dry coolers, and/or cooling towers, are utilized to cool electronic equipment. For example, electronic equipment, such as computers, servers, storage devices, network equipment, power supplies, computing systems, and/or information technology (IT) hardware or infrastructure, may generate substantial amounts of heat during operation. In order to facilitate proper operation of such electronic equipment, the generated heat should be transferred and/or rejected to another suitable location or environment in order to maintain operating temperatures of the electronic equipment below relevant threshold temperatures. It will be appreciated that some facilities, such as data centers, may house considerable amounts of electronic equipment that generate heat in a relatively small area. Accordingly, chiller systems may be implemented, along with other cooling system components, to enable rejection of heat generated by such electronic equipment.

In some implementations, the chiller systems may operate to cool a fluid that is placed in a heat exchange relationship with the electronic equipment. For example, some cooling systems may include coolant distribution units (CDUs) that include a heat exchanger configured to transfer heat between a conditioning fluid generated (e.g., cooled) by the chiller system and a coolant that is placed in a heat exchange relationship with the electronic equipment. The conditioning fluid cooled by the chiller system may be a flow of water (e.g., facility water) supplied or provided by a facility housing the electronic equipment (e.g., data center), and the coolant may be another flow of water (e.g., technical water, IT water) suitable for placing in a heat exchange relationship with the electronic equipment. The flow of water cooled by the chiller system may not be suitable for placing in a heat exchange relationship with the electronic equipment. Therefore, the heat exchanger of the CDU may isolate the conditioning fluid from the electronic equipment.

Additionally, or alternatively, some cooling systems may include a chiller system having a working fluid circuit configured to circulate a working fluid (e.g., refrigerant) to cool a conditioning fluid (e.g., water, glycol, water and glycol mixture), and a conditioning fluid circuit configured to circulate the conditioning fluid between the chiller system and the electronic equipment. More specifically, the conditioning fluid circuit is configured to place the conditioning fluid in a heat exchange relationship with the working fluid circulated through the working fluid circuit of the chiller system and is also configured to place the conditioning fluid in a heat exchange relationship with the electronic equipment. In other embodiments, the chiller system may be configured to cool the working fluid and direct the working fluid to the electronic equipment to place the working fluid in a heat exchange relationship with the electronic equipment, such as via a chilled plate, a tube, a flow path, a channel, a vessel, and/or immersion cooling techniques. In such embodiments, the cooling system may or may not include a conditioning fluid circuit configured to place a conditioning fluid in a heat exchange relationship with the electronic equipment.

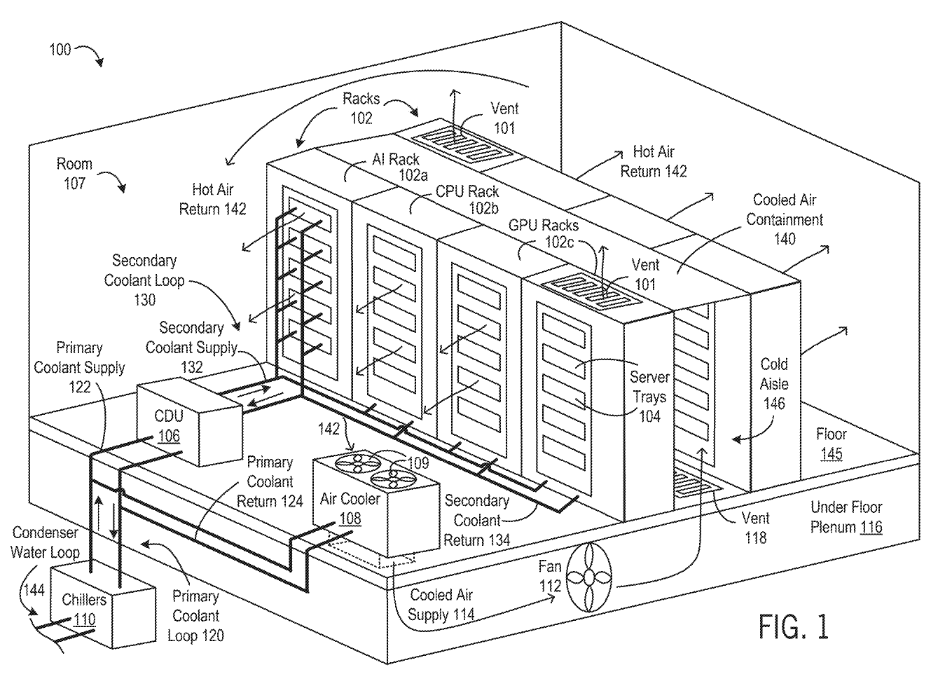

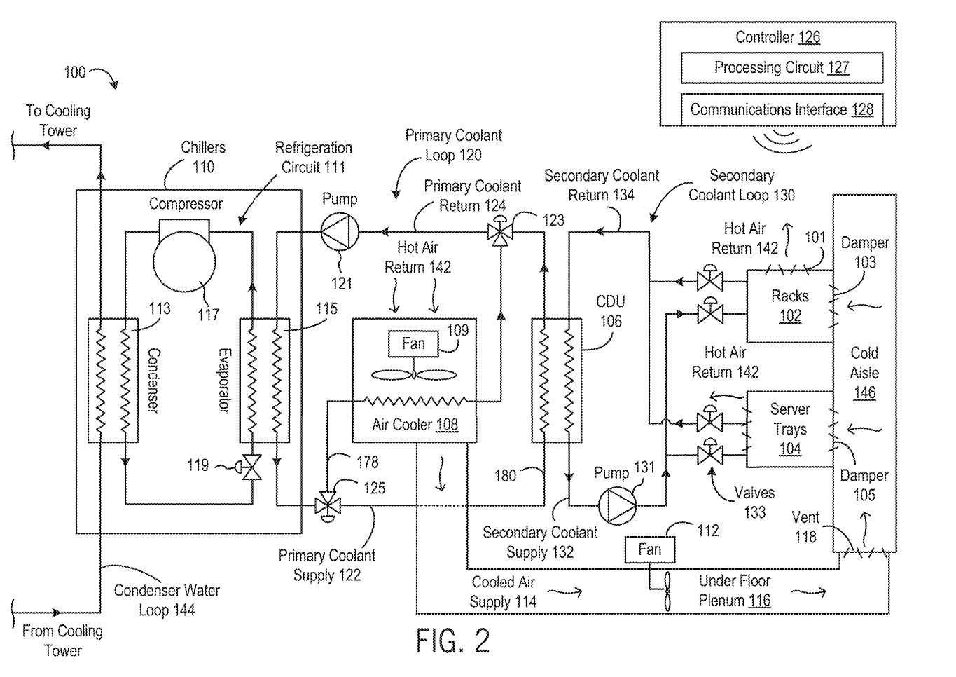

Referring now to FIGS. 1 and 2, a data center cooling system 100 (e.g., computer cooling system) is shown, according to an exemplary embodiment. FIG. 1 is a perspective view of a data center room 107 served by data center cooling system 100, whereas FIG. 2 is a block diagram of data center cooling system 100. Data center room 107 is shown to include several racks 102 (e.g., cabinets), such as racks 102a, 102b, and 102c(e.g., collectively racks 102) containing server trays 104 (e.g., server blades, server boxes, computer enclosures, other computing devices, etc.). Racks 102 may be arranged in rows (e.g., side-to-side) to form aisles between adjacent rows of racks 102. In some embodiments, the aisles form an alternating sequence of cold aisles and hot aisles on opposite sides of racks 102. For example, the space between the two rows of racks 102 in FIG. 1 is shown as a cold aisle 146 which provides a cooled air supply 114 to racks 102. Cold aisle 146 may be bounded on opposite sides by racks 102, on the bottom by floor 145 (i.e., the floor of data center room 107), and on the top by a cooled air containment 140 (e.g., a solid surface) to contain cooled air supply 114 within cold aisle 146. In some embodiments, cooled air containment 140 also extends vertically along the ends of cold aisle 146 to form a wall perpendicular to both the top surface of cooled air containment 140 and the front and rear surfaces of racks 102 (i.e., the surfaces on which server trays 104 are visible) to prevent cooled air supply 114 from escaping cold aisle 146 via the ends.

In some embodiments, the adjacent rows of racks 102 are arranged front-to-front (i.e., such that the front surfaces of adjacent rows of racks 102 face each other) and back-to-back (i.e., such that the rear surfaces of adjacent rows of racks 102 face each other). For example, as shown in FIG. 1, cold aisle 146 is located between the rear surfaces of adjacent rows of racks 102, whereas the front surfaces of racks 102 face toward hot aisles. In some embodiments, a vent 118 is located along floor 145 of cold aisle 146 to allow cooled air supply 114 to flow into cold aisle 146 from an under floor plenum 116. Racks 102 may draw or receive cooled air supply 114 into racks 102 from cold aisle 146 and pass cooled air supply 114 over heat-producing data center equipment contained within racks 102 (e.g., CPUs, GPUs, dual inline memory modules (DIMMs), servers, power supplies, etc.) which transfer heat to cooled air supply 114. The heated airflow then exits racks 102 through the front surfaces of racks 102 (i.e., the surfaces opposite cold aisle 146) and/or through the top surfaces of racks 102 via vents 101. The heated airflow exiting racks 102 then flows into data center room 107 as a hot air return 142.

In some embodiments, racks 102 can be designated as a particular type based on the type of computing devices they contain (e.g., CPUs, GPUs, DIMMs, ASICs, etc.) and/or based on the type of computing application they run during operation (e.g. AI applications, high performance computing applications, standard computing applications, etc.). For example, rack 102a is shown as an AI rack, rack 102b is shown as a CPU rack, and racks 102c are shown as GPU racks. Similarly, server trays 104 can be designated as AI server trays, CPU server trays, or GPU server trays based on the type of computing devices within server trays 104 and/or the type of computing applications by server trays 104. In some embodiments, data center cooling system 100 uses the type of racks 102 and/or server trays 104 to determine the amount of cooling to provide to each of racks 102 and/or server trays 104. For example, AI rack 102a and GPU racks 102c may require a higher amount of cooling whereas CPU rack 102b may require a lower amount of cooling. Similarly, AI server trays and GPU server trays may require a higher amount of cooling whereas CPU server trays may require a lower amount of cooling.

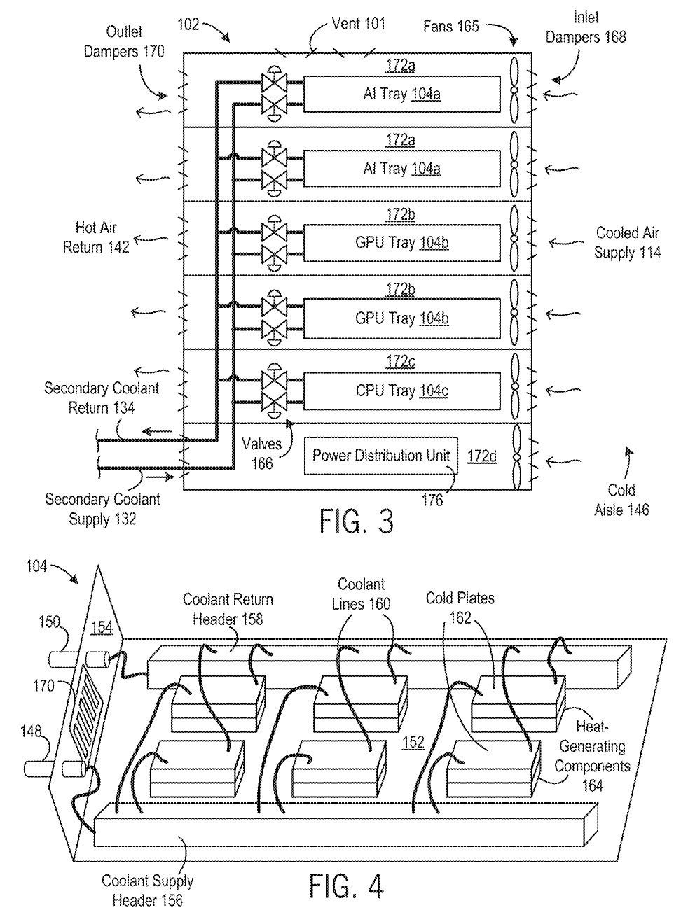

In various embodiments, racks 102 may include top vents 101 located on the top surfaces of racks 102, front vents aligned with each of server trays 104 on the front surfaces of racks 102, or a combination of top vents 101 and front vents. In some embodiments, one or more of racks 102 includes a top vent 101, whereas one or more other racks 102 include front vents. In racks 102 with top vents 101, some or all of the internal volume within such racks 102 may by fluidly connected to allow some or all of the airflow through such racks 102 to exit racks 102 via top vents 101. In racks 102 with front vents aligned with server trays 104, some or all of the internal volume within racks 102 may be portioned into separate compartments within which one or more of server trays 104 are contained. Each compartment may receive a separate airflow stream to provide targeted cooling to the heat-generating equipment contained within the corresponding compartment. One example of how racks 102 can be partitioned into isolated compartments is described in greater detail with reference to FIG. 3. Although only one of GPU racks 102c is shown with top vents 101 in FIG. 1, it is contemplated that any number or type of racks 102 can include top vents 101 and/or or front vents regardless of the type of rack 102. For example, any of AI rack 102a, CPU rack 102b, and/or GPU racks 102c can include front vents and/or top vents 101 in various embodiments.

Still referring to FIGS. 1 and 2, data center cooling system 100 is shown to include air cooling equipment (shown in subsequent figures as air cooling system 230) which provides air cooling to racks 102. The air cooling equipment are shown to include an air cooler 108 and fans 109 and 112 which operate to circulate airflow between air cooler 108 and racks 102. Fan 109 may be positioned to move hot air return 142 from data center room 107 into and through air cooler 108. Air cooler 108 may include any of a variety of airside HVAC equipment configured to provide cooling to hot air return 142 and/or generate cooled air supply 114. For example, air cooler 108 may include one or more computer room air conditioner (CRAC) units, computer room air handler (CRAH) units, direct evaporative cooling (DEC) units, indirect evaporative cooling (IEC) units, free cooling units (e.g., airside economizers), or any other type of airside HVAC equipment. Air cooler 108 may include one or more heat exchangers configured to absorb heat from hot air return 142 to generate cooled air supply 114. In various embodiments, air cooler 108 can be configured to provide mechanical cooling, free cooling, or a combination of mechanical cooling and free cooling to generate cooled air supply 114. For example, air cooler 108 can include any combination of mechanical cooling and free cooling components, as described U.S. Patent No. 9,982,903 granted May 29, 2018, the entire disclosure of which is incorporated by reference herein. Fan 109 can be operated to adjust the airflow rate of cooled air supply 114 and/or the amount of cooling provided to hot air return 142 to generate cooled air supply 114 by controlling the rate at which the airflow passes through air cooler 108.

In some embodiments, air cooler 108 generates cooled air supply 114 by removing heat from hot air return 142. For example, as shown in FIG. 2, air cooler 108 may include an internal heat exchanger (e.g., an air-to-liquid heat exchanger, a cooling coil, etc.) configured to transfer heat from the airflow passing through air cooler 108 into a primary coolant circulating through air cooler 108 via the heat exchanger. In some embodiments, air cooler 108 is configured to generate cooled air supply 114 by exhausting hot air return 142 (e.g., outdoors or into another space other than data center room 107) and drawing cool air into air cooler 108 (e.g., from outdoors or another space) to replace the exhausted hot air return 142. For example, air cooler 108 may operate as an airside economizer configured to provide free cooling to data center room 107 and/or racks 102 when outdoor temperature conditions permit the use of outdoor air. In various embodiments, air cooler 108 may generate cooled air supply 114 by mechanical cooling (e.g., removing heat from hot air return 142), by free cooling (e.g., replacing some or all of hot air return 142 with cooler outdoor air), or by using a combination of mechanical cooling and free cooling.

Air cooler 108 may deliver cooled air supply 114 into under floor plenum 116 which occupies a space below floor 145 of data center room 107. Fan 112 may be located within under floor plenum 116 and configured to move cooled air supply 114 through under floor plenum 116 and into cold aisle 146 via vent 118. Fan 112 can be operated to control the flow rate of cooled air supply 114 through under floor plenum 116 and into cold aisle 146. In some embodiments, data center cooling system 100 may include dampers 103 positioned at the air inlets of racks 102 (e.g., between racks 102 and cold aisle 146 as shown in FIG. 2). Dampers 103 can be operated to modulate the amount of airflow into each of racks 102 individually. Similarly, data center cooling system 100 may include dampers 105 positioned at the air inlets of server trays 104 (e.g., between server trays 104 and cold aisle 146 as shown in FIG. 2). In some embodiments, dampers 103 are used for racks 102 in which some or all of the internal volume is fluidly connected such that the amount of airflow into each rack 102 is controllable at the rack level. Conversely, dampers 105 may be used for racks 102 which are subdivided into compartments to control the airflow through each compartment individually. Although dampers 103 and 105 are shown at the inlets of racks 102 and server trays 104 respectively in FIG. 2, it is contemplated that dampers 103 and dampers 105 may be located at the outlets of racks 102 and server trays 104 or otherwise positioned within racks 102 to control the amount of airflow through each of racks 102 and/or compartments of racks 102.

Still referring to FIGS. 1 and 2, data center cooling system 100 is shown to include liquid cooling equipment (shown in subsequent figures as liquid cooling system 220) which provides liquid cooling to racks 102. The liquid cooling equipment are shown to include a coolant distribution unit (CDU) 106, chillers 110 (e.g., heating, ventilation, air conditioning, and/or refrigeration (HVAC&R) equipment), a primary coolant loop 120, a secondary coolant loop 130, and a condenser water loop 144. Chillers 110 may be configured to provide cooling to a primary coolant (e.g., water, glycol, CO2, ammonia, etc.) which circulates between chillers 110, air cooler 108, and CDU 106 via primary coolant loop 120. As shown in FIG. 2, chillers 110 may include an internal refrigeration circuit 111 (e.g., working fluid circuit, vapor compression circuit) including a compressor 117, a condenser 113, an expansion valve 119, and an evaporator 115. Compressor 117 can be configured to circulate a refrigerant between condenser 113 and evaporator 115 via refrigeration circuit 111. Compressor 117 operates to compress the refrigerant to a high pressure, high temperature state. The compressed refrigerant flows through condenser 113, which transfers heat from the refrigerant in refrigeration circuit 111 to the water in condenser water loop 144. The cooled refrigerant then flows through expansion valve 119, which expands the refrigerant to a low temperature, low pressure state. The expanded refrigerant flows through evaporator 115, which transfers heat from the primary coolant in primary coolant loop 120 to the refrigerant in refrigeration circuit 111. In some embodiments, condenser water loop 144 circulates water or another coolant between condenser 113 and a cooling tower or other location (e.g., another heat exchanger) where the water rejects heat before returning to condenser 113.

In various embodiments, primary coolant loop 120 circulates the primary coolant between chillers 110 and one or both of CDU 106 and air cooler 108. Primary coolant loop 120 may include a pump 121 configured to circulate the primary coolant within primary coolant loop 120. Pump 121 can be operated to control the flow rate of the primary coolant within primary coolant loop 120. In some embodiments, primary coolant loop 120 includes one or more valves 123 and 125 configured to control the flow of the primary coolant through branches 178 and 180 of primary coolant loop 120. Branch 180 may pass through CDU 106, whereas branch 178 may pass through air cooler 108. In some embodiments, as shown in FIG. 2, valves 123 and 125 may be three-way valves positioned at the intersections of branches 178 and 180 (i.e., the location at which primary coolant loop 120 splits into branches 178 and 180) and can be operated to control the flow of the primary coolant supply 122 from chillers 110 to CDU 106 and/or to air cooler 108. Alternatively, valves 123 and 125 can be two-way valves having a single inlet and a single outlet (e.g., on/off valves, adjustable valves, modulating valves, etc.) located along each branch 178 and 180 of primary coolant loop 120 such that valves 123 and 125 can be operated to control the flow of the primary coolant to each of air cooler 108 and CDU 106 individually. In various embodiments, such two-way valves can be located between the intersections shown in FIG. 2 and air cooler 108 (e.g., upstream and/or downstream of air cooler 108), between the intersections shown in FIG. 2 and CDU 106 (e.g., upstream and/or downstream of CDU 106), or otherwise positioned along branches 178 and 180 to selectively control the flow rate of primary coolant supply 122 along each of branches 178 and 180.

The liquid coolant in primary coolant loop 120 is cooled by chillers 110 in evaporator 115 to generate primary coolant supply 122. Although only one evaporator 115 is shown in FIG. 2 for ease of illustration, it is contemplated that primary coolant loop 120 may include one or more evaporators 115 arranged in parallel (e.g., parts of parallel chillers 110) or in series (e.g., parts of series chillers 110) to provide cooling to the liquid coolant circulating in primary coolant loop 120. Primary coolant supply 122 flows through primary coolant loop 120 into branch 178 which passes through air cooler 108 and/or branch 180 which passes through CDU 106. The primary coolant absorbs heat from hot air return 142 in air cooler 108 and/or from the secondary coolant in CDU 106 to generate primary coolant return 124. Primary coolant return 124 then returns from air cooler 108 and/or CDU 106 to chillers 110 to be cooled once again and the cycle repeats.

In various embodiments, the liquid coolant circulating in primary coolant loop 120 can be cooled using any combination of mechanical cooling and/or free cooling. For example, in one embodiment a first portion (e.g., a first branch) of primary coolant loop 120 may pass through chillers 110 to receive mechanical cooling from chillers 110, whereas a second portion (e.g., a second branch) of primary coolant loop 120 may pass through one or more free cooling devices (e.g., outdoor air heat exchangers, cooling towers, etc.) to receive free cooling when outdoor temperature conditions permit using free cooling. Several examples of how a hybrid mechanical cooling and free cooling system can be constructed are described in detail in U.S. Patent No. 9,982,903 incorporated by reference above.

In some embodiments, data center cooling system 100 includes multiple primary coolant loops 120 configured to circulate the primary coolant at different temperatures. For example, a first primary coolant loop 120 may be configured to circulate a relatively higher temperature coolant, a second primary coolant loop 120 may be configured to circulate relatively colder temperature coolant, and a third primary coolant loop 120 may be configured to circulate coolant at a medium temperature between the relatively higher and lower temperatures. The

CDU 106 can be configured to transfer heat between the primary coolant in primary coolant loop 120 and the secondary coolant (e.g., water, glycol, CO2, ammonia, etc.) in secondary coolant loop 130. It is expected that the secondary coolant in secondary coolant loop 130 is warmer than the primary coolant in primary coolant loop 120 and thus the direction of heat transfer within CDU 106 is from the secondary coolant to the primary coolant (i.e., from secondary coolant loop 130 to primary coolant loop 120). In various embodiments, the primary coolant and the secondary coolant may be the same or different coolants and may be kept fluidly separate from each other by containing them within their respective coolant loops 120 and 130. CDU 106 is shown as a heat exchanger (e.g., a liquid-to-liquid heat exchanger, a heat exchange coil, etc.) which receives primary coolant supply 122 from primary coolant loop 120 and secondary coolant return 134 from secondary coolant loop 130. CDU 106 may transfer heat from the relatively warmer secondary coolant return 134 into the relatively colder primary coolant supply 122 to provide cooling to the secondary coolant and generate secondary coolant supply 132.

Secondary coolant loop 130 can be configured to circulate the secondary coolant between CDU 106 and one or both of racks 102 and server trays 104. Secondary coolant loop 130 may include a pump 131 configured to circulate the secondary coolant within secondary coolant loop 130. Pump 131 can be operated to control the flow rate of the secondary coolant within secondary coolant loop 130 and/or the rate of heat transfer between the primary coolant and the secondary coolant in CDU 106. In some embodiments, secondary coolant loop 130 includes one or more valves 133 configured to control the flow of the secondary coolant through racks 102 and/or server trays 104. In various embodiments, valves 133 may be located at the coolant inlets of racks 102 or server trays 104 and/or at the coolant outlets of racks 102 or server trays 104 to control the flow of the secondary coolant through each of racks 102 and/or server trays 104 individually. Although valves 133 are shown at both the inlets and outlets of racks 102 and server trays 104 in FIG. 2, it is contemplated that such an arrangement may be redundant and that a single valve located at either the inlet or the outlet of each of racks 102 or server trays 104 may be sufficient to control the flow of the secondary coolant through each of racks 102 and server trays 104 individually.

In some embodiments, secondary coolant loop 130 provides the secondary coolant to one or more of racks 102 in parallel. For example, as shown in FIG. 1, the three racks 102b and 102c are shown receiving secondary coolant supply 132 from secondary coolant loop 130 and discharging secondary coolant return 134 as an output of racks 102. Such racks 102b and 102c may have internal valves (e.g., valves 166 shown in FIG. 3), pumps, or other flow control devices which can be operated to independently control the flow of secondary coolant supply 132 to each of server trays 104 and/or individual heat-generating components 164 located within racks 102b and 102c, as described in greater detail with reference to FIGS. 3 and 4. In some embodiments, secondary coolant loop 130 provides the secondary coolant directly to one or more of server trays 104 in parallel. For example, as shown in FIG. 1, rack 102a is shown with secondary coolant supply 132 being delivered to each of server trays 104 of rack 102a in parallel. In various embodiments, secondary coolant loop 130 can deliver the secondary coolant to one or more of racks 102 and/or one or more of server trays 104 in parallel.

Although server trays 104 are shown separate from racks 102 in FIG. 2, it is understood that server trays 104 may be installed within racks 102 and thus may be considered components of racks 102 in some embodiments. The separate depiction of racks 102 and server trays 104 in FIG. 2 is intended to illustrate that the air cooling system (e.g., air cooler 108, fans 109 and 112, dampers 103 and 105, etc.) may provide cooled air supply 114 directly to one or more of server trays 104 (e.g., directly from cold aisle 146) without first requiring cooled air supply 114 to enter the racks 102 within which such server trays 104 are contained. For example, one or more of server trays 104 may have a cooled air intake located along an edge or surface of racks 102 adjacent to cold aisle 146 and configured to receive cooled air supply 114 directly from cold aisle 146 (e.g., via dampers 105). Accordingly, the amount of cooling provided to each of server trays 104 by the air cooling system can be independently adjusted by controlling the airflow rate of cooled supply air 114 and/or the temperature of cooled supply air 114 provided to each of server trays 104 individually. Other server trays 104 may be located within a shared volume within racks 102 and configured to receive cooled air supply 114 after cooled air supply 114 enters racks 102. For example, racks 102 may include dampers 103 which can be operated to control the flow rate of cooled air supply 114 into each of racks 102 individually. In racks 102 with a single large compartment containing multiple server trays 104, cooled air supply 114 may pass across or through multiple server trays 104 within a given rack 102 after entering the rack 102 (e.g., via dampers 103).

Although AI rack 102a is the only type of racks 102 shown in FIG. 1 as receiving the secondary coolant directly from secondary coolant loop 130 to each of server trays 104 within rack 102a, it is contemplated that any of racks 102 can be connected to secondary coolant loop 130 at the server tray level (i.e., with a separate coolant inlet and outlet for each of server trays 104 within the rack) and that such connectivity is not limited to racks 102 designated as AI racks. For example, any of CPU rack 102b and/or GPU racks 102c can also or alternatively be connected to secondary coolant loop 130 at the server tray level in various embodiments. Similarly, while CPU rack 102b and GPU racks 102c are the only type of racks 102 shown in FIG. 1 with a single coolant inlet and single coolant outlet connecting to secondary coolant loop 130, it is contemplated that any of racks 102 can be connected to secondary coolant loop 130 at the rack level (i.e., with a single coolant inlet and outlet for the rack as a whole) and that such connectivity is not limited to racks designated as CPU racks or GPU racks. For example, AI rack 102a can also or alternatively be connected to secondary coolant loop 130 at the rack level in some embodiments.

In some embodiments, primary coolant loop 120 and/or secondary coolant loop 130 supply a liquid coolant (e.g., water, glycol, etc.) to racks 102, server trays 104, and/or to individual heat-generating components installed on server trays 104 (e.g., CPUs, GPUs, etc.) to provide targeted cooling to such components. However, it is contemplated that data center cooling system 100 is not limited to using liquid coolants in primary coolant loop 120 and/or secondary coolant loop 130, but rather can use any of a variety of fluid coolants in various embodiments (e.g., gas coolants, liquid coolants, vapor coolants, mixed phase (liquid/vapor, liquid/gas) coolants, and/or any other type of fluid coolant). Accordingly, it should be understood that all references to liquid coolants throughout the present disclosure including the claims presented herein can be replaced with any other type of fluid coolant without departing from the teachings of the present disclosure.

Referring now to FIG. 3, one of racks 102 is shown in greater detail, according to an exemplary embodiment. Rack 102 is shown to include several compartments 172a, 172b, 172c, and 172d (collectively compartments 172) containing different types of server trays 104 and a power distribution unit (PDU) 176. In particular, compartments 172a are shown containing AI trays 104a, compartments 172b are shown containing GPU trays 104b, compartment 172c is shown containing CPU tray 104c, and compartment 172d is shown containing PDU 176. As noted above, the types of server trays 104 within compartments 172 may correspond to the types of computing applications run by server trays 104 and/or the types of computing devices located on server trays 104 (e.g., AI applications, high performance computing applications, GPUs, CPUs, DIMMS, etc.).

In some embodiments, compartments 172 are fluidly isolated from each other (e.g., by solid surfaces within racks 102 forming upper and lower boundaries of compartments 172) such that the airflow streams through compartments 172 do not mix with each other within racks 102. Accordingly, each of compartments 172 may receive a separate stream of cooled air supply 114 from cold aisle 146 for use in cooling the heat-producing data center equipment therein. The streams of cooled air supply 114 may be kept separate from each other within racks 102 such that each stream of cooled air supply 114 cools a corresponding compartment 172. In other embodiments, racks 102 may not include compartments 172 (or one or more of compartments 172 may be joined into a larger compartment) such that some or all of the internal volume within racks 102 is fluidly connected. In such an embodiment, racks 102 may receive one or more streams of cooled air supply 114 from cold aisle 146 and may allow the streams of cooled air supply 114 to mix or join within racks 102.

In some embodiments, racks 102 include inlet dampers 168 positioned at the cold air intake of racks 102 (e.g., between cold aisle 146 and compartments 172). Inlet dampers 168 may be aligned with compartments 172 and individually operated to independently control the flow of cooled air supply 114 into and through each of compartments 172. Dampers 103 and 105 shown in FIG. 2 may be types of inlet dampers 168 shown in FIG. 3. Similarly, racks 102 may include inlet dampers 168 positioned at the hot air exhaust of racks 102 (e.g., between compartments 172 and the hot aisle or data center room 107). Outlet dampers 170 may be aligned with compartments 172 and individually operated to independently control the flow of cooled air supply 114 out of and through each of compartments 172. Although compartments 172 are shown equipped with both inlet dampers 168 and outlet dampers 170 in FIG. 3, it is contemplated that such an arrangement may be redundant and that only one of inlet dampers 168 or outlet dampers 170 may be installed and used to control the airflow through each of compartments 172 in some embodiments. Alternatively, both inlet dampers 168 and outlet dampers 170 may be installed and used to control the airflow through compartments 172 in some embodiments.

In some embodiments, cooled air supply 114 within cold aisle 146 is maintained at an air pressure above the air pressure within data center room 107 such that the pressure differential causes cooled air supply 114 to flow through compartments 172 when inlet dampers 168 and/or outlet dampers 170 are open. For example, air cooler 108 and/or fan 112 may be operated to maintain cold aisle 146 at a positive air pressure relative to the air pressure within data center room 107. In some embodiments, racks 102 include fans 165 positioned within each compartment 172 (e.g., upstream or downstream of server trays 104). Fans 165 can be operated to independently control the flow rate of cooled air supply 114 through each of compartments 172 to provide different air flow rates to different server trays 104 within a given rack 102.

For racks 102 that contain multiple compartments 172, each compartment 172 may be equipped with an inlet damper 168, outlet damper 170, and/or fan 165. These components can be operated to independently control the flow rate of cooled air supply 114 through each compartment 172, and thus modulate the amount of cooling provided to each of server trays 104 by cooled air supply 114. For racks 102 that do not contain multiple compartments 172, such racks 102 may include one or more of inlet dampers 168, outlet dampers 170, and/or fans 165 which can be operated to control the flow rate of cooled air supply 114 through the rack 102 as a whole. In this way, each rack 102 can be provided with a different amount of air cooling either at the rack level or at the server tray level. In some embodiments, inlet dampers 168 and/or outlet dampers 170 can be replaced with vents or held permanently open to provide the same functionality as a vent. In such embodiments, airflow through each of compartments 172 can be controlled by operating fans 165 and/or by controlling the air pressure within cold aisle 146.

Still referring to FIG. 3, rack 102 is shown to include valves 166. Valves 166 may be located along secondary coolant loop 130 and operated to control the flow of the secondary coolant through rack 102 and/or server trays 104. In various embodiments, valves 166 can be located along secondary coolant supply 132 (e.g., upstream of server trays 104), along secondary coolant return 134 (e.g., downstream of server trays 104), or in both locations as shown in FIG. 3. However, it is contemplated that positioning valves 166 both upstream and downstream of server trays 104 may be redundant and that only one of an upstream valve 166 or a downstream valve 166 may be required to control the flow of the secondary coolant through rack 102 and/or server trays 104. In some embodiments, rack 102 includes one or more valves 166 within each of compartments 172 or otherwise positioned to control the flow of the secondary coolant to each of server trays 104 individually. Such an arrangement allows each of server trays 104 to receive a different flow rate of the secondary coolant from secondary coolant supply 132 (e.g., by operating valves 166) to modulate the amount of liquid cooling provided to each of server trays 104 independently. Although not explicitly shown in FIG. 3, it is contemplated that PDU 176 may also be cooled by secondary coolant loop 130 and may receive a flow of secondary coolant supply 132 in some embodiments.

In some embodiments, valves 166 and/or valves 133 can be operated to open or close different branches of secondary coolant loop 130. For example, valves 133 shown in FIG. 2 can be closed to prevent the secondary coolant from flowing into and through one or more of racks 102 or server trays 104 connected in series with valves 133, or opened to allow the secondary coolant to flow through into and through one or more of racks 102 or server trays 104 connected in series with valves 133. Similarly, valves 166 shown in FIG. 3 can be opened or closed to allow the secondary coolant to flow through individual server trays 104 within a given rack 102 while preventing the secondary coolant from flowing through other server trays 104 within a given rack 102. Valves 166 and 133 can be modulated between fully open positions and fully closed positions (i.e., set to any position between and including fully open and fully closed) to selectively control the amount of proportion of the secondary coolant that flows through each of racks 102 and/or server trays 104. In this way, the flow of the secondary coolant can be controlled (e.g., increased, decreased, etc.) or cut-off entirely to some or all of racks 102 or server trays 104 based on their individual cooling requirements. In some embodiments, valves 166 and 133 can be closed to allow some racks 102 or server trays 104 to be disconnected from secondary coolant loop 130 (e.g., for maintenance, replacement, etc.). Valves 166 and 133 can also or alternatively be closed to increase the efficiency of pump 131 by preventing pressure losses within secondary coolant loop 130 caused by pumping the secondary coolant through racks 102 or server trays 104 that do not require liquid cooling.

Referring now to FIG. 4, one of server trays 104 is shown in greater detail, according to an exemplary embodiment. Server tray 104 is shown to include a surface 152 (e.g., a bottom surface, a board, a substrate, etc.) on which one or more heat-generating components 164 are mounted or installed. Heat-generating components 164 may include any type of computing device or other data center component that generates heat during operation (e.g., CPUs, GPUs, ASICs, DIMMs, power supplies, etc.). Server tray 104 is shown to include cold plates 162 thermally coupled to heat-generating components 164 (e.g., positioned on or near heat-generating components 164 to facilitate heat transfer between cold plates 162 and heat-generating components 164) and configured to absorb heat from heat-generating components 164 during operation. Cold plates 162 may include heat sinks, tubes, liquid-to-solid heat exchangers, or any other structure configured to draw heat away from heat-generating components 164. Cold plates 162 may receive flows of the secondary coolant from secondary coolant loop 130 and transfer heat from heat-generating components 164 into the secondary coolant.

Server tray 104 is shown to include a front surface 154 having a coolant inlet port 148 and a coolant outlet port 150. Coolant inlet port 148 may be connected to secondary coolant supply 132 and may receive a flow of the chilled secondary coolant from secondary coolant loop 130. The chilled secondary coolant may flow from coolant inlet port 148 into a coolant supply header 156. Coolant supply header 156 may be connected to each of cold plates 162 via coolant lines 160 and may deliver the chilled secondary coolant to cold plates 162. The secondary coolant absorbs heat from cold plates 162 and thus provides cooling to heat-generating components 164 thermally coupled to cold plates 162. The warmed secondary coolant then flows from cold plates 162 into coolant return header 158 via coolant lines 160. Coolant return header 158 may be fluidly coupled with coolant outlet port 150 and configured to discharge the warmed secondary coolant back to secondary coolant loop 130 via coolant outlet port 150.

In some embodiments, cold plates 162 also or alternatively include fins, plates, solid-to-air heat exchangers, or other structures configured to transfer heat from cold plates 162 into cooled air supply 114 flowing across server tray 104. Cooled air supply 114 may flow across server tray 104 and absorb heat from heat-generating components 164 either directly or via cold plates 162. The warmed airflow may then exit server tray 104 via front surface 154 through outlet damper 170 and/or a front vent in various embodiments.

Referring generally to FIGS. 1-4, data center cooling system 100 may include a variety of sensors (e.g., temperature sensors, flow rate sensors, pressure sensors, etc.) positioned to measure the temperatures, flow rates, pressures, or other conditions of the airflow and liquid coolant at various locations within data center cooling system 100. For example, data center cooling system 100 may include air sensors positioned at the inlet or outlet of air cooler 108 (e.g., upstream or downstream of the heat exchanger within air cooler 108), within under-floor plenum 166, at the air inlet or outlet of each rack 102 (e.g., upstream or downstream of server trays 104), at the air inlet or outlet of each of compartments 172 (e.g., proximate to inlet dampers 168 or outlet dampers 170), within compartments 172, within data center room 107, or otherwise within the data center to measure the temperatures, flow rates, pressures, and/or other conditions of the airflow at the locations of the air sensors. For example, data center cooling system 100 may include flow rate sensors and/or temperature sensors configured to measure the flow rate or temperature of cooled air supply 114 entering each of racks 102 or each of compartments 172 and/or the flow rate or temperature of hot air return 142 exiting each of racks 102 or each of compartments 172 independently.

Data center cooling system 100 may include liquid coolant or refrigerant sensors positioned at the coolant inlets or outlets of chillers 110 (e.g., along primary coolant loop 120 upstream or downstream of evaporator 115), at any location within refrigeration circuit 111, at the coolant inlets or outlets of CDU 106 (e.g., along primary coolant loop 120 upstream or downstream of CDU 106, along secondary coolant loop 130 upstream or downstream of CDU 106), at the inlets or outlets of individual racks 102 or server trays 104 (e.g., along secondary coolant supply 132 or secondary coolant return 134), or immediately upstream or downstream of individual heat-generating components 164 within server trays 104 to measure the temperatures, flow rates, pressures, and/or other conditions of the liquid coolant or refrigerant at the locations of the liquid coolant or refrigerant sensors. For example, data center cooling system 100 may include flow rate, pressure, or temperature sensors configured to measure the flow rate, pressure, or temperature of the primary coolant entering or exiting chillers 110 (e.g., position upstream or downstream of chillers 110 along primary coolant loop 120), the secondary coolant entering or exiting CDU 106 (e.g., along secondary coolant loop 130 upstream or downstream of CDU 106), the secondary coolant entering or exiting racks 102 or server trays 104 (e.g., along secondary coolant loop 130 upstream or downstream or racks 102 or server trays 104), the refrigerant in refrigeration circuit 111 (e.g., between any of condenser 113, expansion valve 119, evaporator 115, and compressor 117), along condenser water loop 144 upstream or downstream of chillers 110, or otherwise positioned to measure any variable state or condition of the refrigerant, primary coolant, secondary coolant, or condenser water any ant location in data center cooling system 100.

In some embodiments, data center cooling system 100 includes temperature sensors configured to measure the temperatures of heat-generating components 164 (e.g., CPU temperatures, GPU temperatures, etc.). Such temperature sensors may be integrated with heat-generating components 164 (e.g., internal thermocouples or other built-in temperature sensors) or additional components of data center cooling system 100 installed to measure the temperatures at or near each of heat-generating components 164. In some embodiments, data center cooling system 100 includes power sensors configured to measure the amount of power delivered to each of racks 102, server trays 104, heat-generating components 164, or other computing devices within the data center. In some embodiments, the power sensors are implemented as wattage sensors, current sensors, or voltage sensors configured to measure the amount of electric power delivered to various components of the data center or measure variables from which power can be derived (e.g., voltage, current, etc.).

Referring particularly to FIG. 2, data center cooling system 100 is shown to include a controller 126. Controller 126 is shown to include a processing circuit 127 and a communications interface 128. Processing circuit 127 may include one or more processors and memory. The processors (shown in subsequent figures as processor 222) may include one or more general purpose or specific purpose processors, application specific integrated circuits (ASIC), one or more field programmable gate arrays (FPGAs), a group of processing components, or other suitable processing components. The processors may be configured to execute computer code or instructions stored in the memory or received from other computer readable media (e.g., CDROM, network storage, a remote server, etc.). The memory (shown in subsequent figures as memory 223) may include one or more devices (e.g., memory units, memory devices, storage devices, etc.) for storing data and/or computer code for completing and/or facilitating the various processes described in the present disclosure. The memory may include random access memory (RAM), read-only memory (ROM), hard drive storage, temporary storage, non-volatile memory, flash memory, optical memory, or any other suitable memory for storing software objects and/or computer instructions. The memory may include database components, object code components, script components, or any other type of information structure for supporting the various activities and information structures described in the present disclosure. The memory may be communicably connected to the processors via processing circuit 127 and may include computer code for executing (e.g., by the processors) one or more processes described herein.

Communications interface 128 may include wired or wireless interfaces (e.g., jacks, antennas, transmitters, receivers, transceivers, wire terminals, etc.) for conducting data communications with various systems, devices, or networks. For example, communications interface 128 may include an Ethernet card and port for sending and receiving data via an Ethernet-based communications network and/or a Wi-Fi transceiver for communicating via a wireless communications network. Communications interface 128 may be configured to communicate via local area networks or wide area networks (e.g., the Internet, a building WAN, etc.) and may use a variety of communications protocols (e.g., BACnet, IP, LON, etc.). Communications interface 128 may be configured to facilitate electronic data communications between controller 126 and various other systems or devices of data center cooling system 100 (e.g., sensors, controllable equipment, etc.) or other external data sources, systems, or devices outside data center cooling system 100. For example, controller 126 may be configured to communicate with any or all of the controllable equipment of data center cooling system 100 (e.g., CDU 106, air cooler 108, fan 109, chillers 110, fan 112, compressor 117, expansion valve 119, pump 121, valve 123, valve 125, valves 133, pump 131, dampers 103, dampers 105, inlet dampers 168, outlet dampers 170, valves 166, fans 165, etc.) and any or all of the sensors in data center cooling system 100 (e.g., any of the temperature sensors, pressure sensors, flow rate sensors, power sensors, etc.).

Controller 126 can be configured to receive measurements from the sensors and operate the controllable equipment of data center cooling system 100 to control the flow rates, pressures, temperatures, or other variable states or conditions of cooled air supply 114, hot air return 142, the refrigerant in refrigeration circuit 111, the condenser water in condenser water loop 144, the primary coolant in primary coolant loop 120, the secondary coolant in secondary coolant loop 130, or any portions thereof. In some embodiments, controller 126 receives reported values of temperatures, power consumption, or other measured or calculated variables from heat-generating components 164, PDU 176, or other data center equipment configured to report their own operating conditions (e.g., temperatures, power consumption, power delivered, computing load, etc.).

Controller 126 can use any of a variety of feedback control processes (e.g., closed-loop control, reset control, etc.), feedforward or predictive control processes (e.g., model predictive control, prediction-based control, etc.), or other control processes to operate the controllable equipment of data center cooling system 100 based on the measured values from installed sensors or reported variables from the data center equipment. Several examples of particular control processes which can be performed by controller 126 are described in detail below. Advantageously, controller 126 can be configured to precisely modulate the amount of cooling provided to each of racks 102, server trays 104, and/or individual heat-generating components 164 (referred to generally as “heat loads”) by both the air cooling equipment and the liquid cooling equipment of data center cooling system 100. Controller 126 can independently adjust the amount of cooling provided individual heat loads within the data center by controlling the air cooling equipment and the liquid cooling equipment that serve each heat load independently. This allows controller 126 to provide targeted cooling to various heat loads as needed without overcooling other heat loads more than necessary to dissipate the amount of heat generated during operation.

In some embodiments, data center cooling system 100 includes some or all of the components, features, or functionality described in U.S. Patent Application No. 17/741,108 filed May 10, 2022, U.S. Patent No. 11,497,144 granted Nov. 8, 2022, U.S. Patent Application No. 18/308,418 filed Apr. 27, 2023, U.S. Patent Application No. 18/308,422 filed Apr. 27, 2023, U.S. Patent Application No. 18/641,658 filed Apr. 22, 2024, Indian Provisional Patent Application No. 202441090506 filed Nov. 2021, 2024, U.S. Provisional Patent Application No. 63/804,615 filed May 12, 2025, U.S. Provisional Patent Application No. 63/804,544 filed May 12, 2025, U.S. Provisional Patent Application No. 63/804,546 filed May 12, 2025, U.S. Provisional Patent Application No. 63/804,553 filed May 12, 2025, and/or U.S. Provisional Patent Application No. 63/804,558 filed May 12, 2025, all of which are incorporated by reference herein in their entireties. For example, controller 126 can be configured to execute any or all of the control processes described in any of the patents, patent applications, or other documents incorporated by reference throughout the present disclosure in the context of data center cooling system 100. Data center cooling system 100 can include any or all of the equipment described in any of the aforementioned documents in various embodiments. In addition to the functionality described in these documents, controller 126 can be configured to execute a variety of new control processes that improve upon the prior art in various ways, several examples of which are described in detail below.

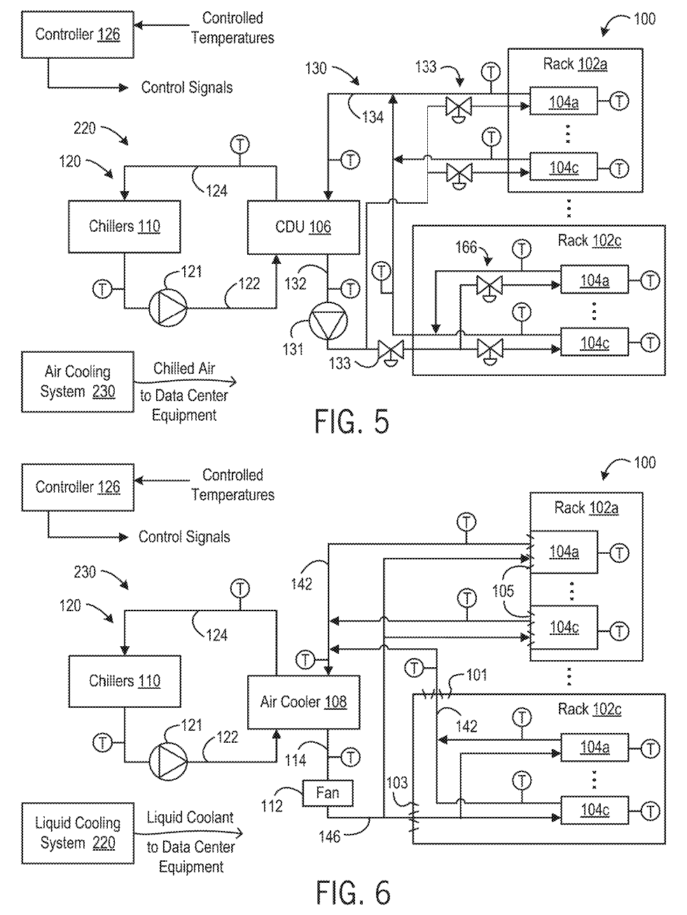

Referring now to FIGS. 5 and 6, data center cooling system 100 is shown in greater detail, according to some embodiments. FIG. 5 illustrates the fluid connections of liquid cooling system 220 including primary coolant loop 120 and secondary coolant loop 130 (referred to herein as liquid cooling loops or liquid cooling circuits). Primary coolant loop 120 circulates a primary coolant between chillers 110 and CDU 106. The primary coolant exits chillers 110 into primary coolant supply 122 and then flows into CDU 106 wherein the primary coolant absorbs heat from the secondary coolant. The primary coolant then exits CDU 106 and flows into primary coolant return 124 after absorbing heat from the secondary coolant in CDU 106. Pump 121 operates to circulate the primary coolant between chillers 110 and CDU 106 and can be located along primary coolant supply 122 and/or primary coolant return 124 in various embodiments. Temperature sensors (shown as circles containing “T” in FIGS. 5 and 6) can be located along primary coolant supply 122 and configured to measure the temperature of the primary coolant exiting chillers 110 or entering CDU 106. Temperature sensors can also or alternatively be located along primary coolant return 124 and configured to measure the temperature of the primary coolant exiting CDU 106 or entering chillers 110.

Secondary coolant loop 130 circulates a secondary coolant between CDU 106, racks 102, and/or server trays 104. The secondary coolant exits CDU 106 after rejecting heat to the primary coolant and flows into secondary coolant supply 132. Valves 133 may be located along secondary coolant supply 132 and can be operated to control the flow of the secondary coolant into each of racks 102 individually. In some embodiments, one or more of racks 102 includes additional valves 166 which can be operated to control the flow of the secondary coolant in to each of server trays 104 individually. Pump 131 operates to circulate the secondary coolant between CDU 106, racks 102, and/or server trays 104 and can be located along secondary coolant supply 132 and/or secondary coolant return 134 in various embodiments. In some embodiments, controller 126 operates CDU 106 to maintain the temperature of the liquid coolant in secondary coolant supply 132 and/or secondary coolant return 134 at or above a dew point temperature of the air within the data center to prevent condensation on liquid lines.

Temperature sensors can be located along any of secondary coolant supply 132 (e.g., at the outlet of CDU 106, at the inlets of racks 102, at the inlets of server trays 104, etc.), secondary coolant return 134 (e.g., at the inlet of CDU 106, at the outlets of racks 102 and/or server trays 104, etc.) and configured to measure the temperature of the secondary coolant at the locations of the temperature sensors. In some embodiments, secondary coolant loop 130 includes a temperature sensor located at the outlet of each of racks 102 and/or server trays 104 and configured to measure the temperatures of the secondary coolant exiting each of racks 102 and/or server trays 104. In some embodiments, data center cooling system 100 includes temperature sensors configured to measure the temperatures of each of racks 102, server trays 104, and/or individual components of data center equipment 240 (e.g., CPU temperatures, GPU temperatures, etc.).

FIG. 6 illustrates the fluid connections of air cooling system 230 including primary coolant loop 120 and an air cooling loop 232. Primary coolant loop 120 may be the same as described with reference to FIG. 5 with the exception that primary coolant loop 120 delivers the primary coolant to air cooler 108. Air cooler 108 transfers heat from the air into the primary coolant to generate cooled air supply 114. Temperature sensors can be located along primary coolant supply 122 and configured to measure the temperature of the primary coolant exiting chillers 110 or entering air cooler 108. Temperature sensors can also or alternatively be located along primary coolant return 124 and configured to measure the temperature of the primary coolant exiting air cooler 108 or entering chillers 110.

Air cooling loop 232 (e.g., an air cooling circuit) circulates air between air cooler 108, racks 102, and/or server trays 104. Cooled air supply 114 exits air cooler 108 and is circulated by fan 112 through cold aisle 146 and into racks 102 via dampers 103 and/or into server trays 104 via dampers 105. Cooled air supply 114 absorbs heat from data center equipment 240 within racks 102 and/or server trays 104 and exits racks 102 and/or server trays 104 via top vents 101 and/or dampers 105. Temperature sensors can be positioned to measure the temperature of the cooled air supply 114 exiting air cooler 108 (e.g., within cold aisle 146, at the inlets of racks 102 and/or server trays 104, etc.), the temperature of the air exiting racks 102 and/or server trays 104 (e.g., immediately downstream of racks 102 and/or server trays 104, at the outlets of racks 102 and/or server trays 104), or any other location within air cooling loop 232. In general, temperature sensors can be located at any of the positions shown in FIGS. 5 and 6 or otherwise located in liquid cooling system 220 and/or air cooling system 230 to measure the temperatures of the primary coolant, secondary coolant, cooled air, or other coolant temperatures at any location within liquid cooling system 220 and/or air cooling system 230.

Some cooling systems implemented with data centers include numerous stages of heat exchange, which may limit an overall efficiency or effectiveness of such cooling systems to transfer and reject heat generated by electronic equipment in data centers. To this end, present embodiments are directed to improved configurations of cooling systems configured to provide cooling to electronic equipment with increased efficiency and effectiveness. For example, certain cooling systems incorporating the techniques described herein include a chiller system that operates to cool a working fluid and direct the working fluid to the electronic equipment to place the working fluid in a heat exchange relationship with the electronic equipment, such as via a chilled plate, a tube, a flow path, a channel, a vessel, and/or immersion cooling techniques. In such embodiments, the cooling system may not include a conditioning fluid circuit configured to place a conditioning fluid in a heat exchange relationship with the electronic equipment. Instead, at least a portion of the working fluid circuit may extend from the chiller system to the electronic equipment, thereby enabling the working fluid to absorb heat from the electronic equipment. Accordingly, certain embodiments discussed herein may not incorporate a CDU that includes a heat exchanger configured to enable heat transfer between two flows of fluid, such as a conditioning fluid cooled by a chiller system and a coolant placed in a heat exchange relationship with electronic equipment. Additionally, certain embodiments discussed herein may not include an evaporator of a chiller system configured to enable heat transfer between a working fluid circulated through the chiller system and a conditioning fluid placed in a heat exchange relationship with the electronic equipment. Therefore, one or more stages of heat transfer typically included in some cooling systems is omitted, which enables enhanced efficiency of the chiller system and increased heat rejection of heat generated by the electronic equipment.

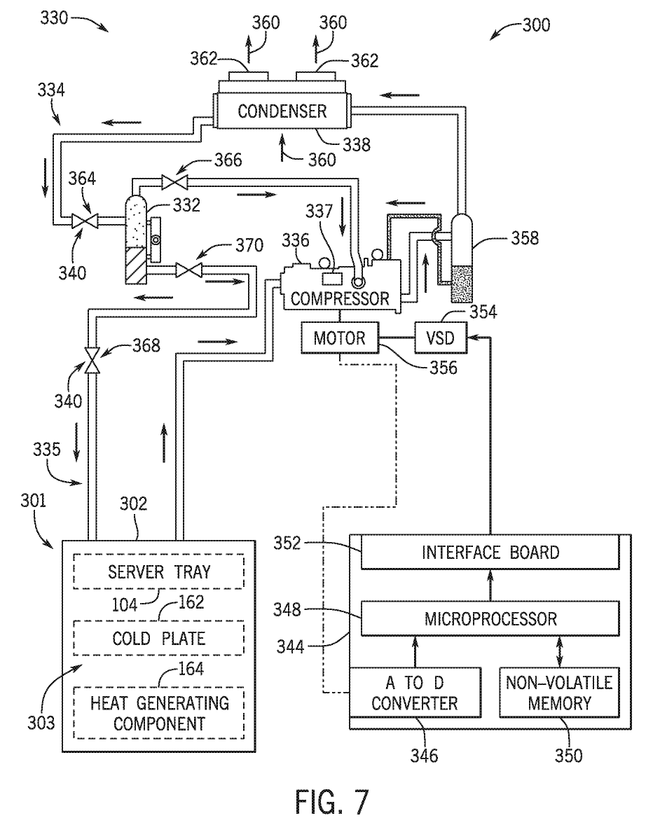

With the preceding in mind, FIG. 7 is a schematic of an embodiment of a cooling system 300 (e.g., computer cooling system, electronic equipment cooling system, data center cooling system) configured to provide cooling to electronic equipment 301. In certain embodiments, the electronic equipment 301 may include an embodiment of a computer enclosure 302 configured to house and/or support computer componentry 303 (e.g., computer components, computer chips), such as one or more server trays 104, one or more cold plates 162, one or more heat-generating components 164, or any combination thereof. Additionally, or alternatively, the electronic equipment 301 may include an embodiment of a rack or cabinet, such as an embodiment of the rack 102, configured to house and/or support multiple computer enclosures 302, each being configured to house and/or support respective computer componentry 303 (e.g., integrated circuits, circuit boards, communication circuitry, processors, servers, server trays, computer chips, memories, routers, switches, controllers, heat-generating components, and/or other computer hardware).

In the illustrated embodiment, the computer cooling system 300 includes a vapor compression system 330 (e.g., mechanical cooling system, air-cooled vapor compression system, chiller system, air-cooled chiller system). For example, the vapor compression system 330 may be a part of an air-cooled chiller. The vapor compression system 330 includes a working fluid circuit 334 (e.g., vapor compression circuit, first working fluid circuit) configured to circulate a working fluid, such as a refrigerant, therethrough with a compressor 336 (e.g., screw compressor, centrifugal compressor, compressor system) disposed along the working fluid circuit 334. The working fluid circuit 334 also includes a flash tank 332, a condenser 338 (e.g., first condenser, heat exchanger, air-cooled condenser), and expansion valves or devices 340. As shown in the illustrated embodiment, at least a portion 335 of the working fluid circuit 334 may extend through the electronic equipment 301 (e.g., one or more components of the computer equipment 301), thereby enabling cooling of the electronic equipment 301 via the working fluid directed along the working fluid circuit 334. The components of the working fluid circuit 334 enable heat transfer between the working fluid and one or more other fluids (e.g., air, water) in order to provide cooling to the electronic equipment 301.

Some examples of working fluids that may be used as a refrigerant in the vapor compression system 330 are hydrofluorocarbon (HFC) based working fluids, for example, R-410A, R-407, R-134a, hydrofluoro olefin (HFO), “natural” working fluids like ammonia (NH3), R-717, carbon dioxide (CO2), R-744, or hydrocarbon-based working fluids, water vapor, or any other suitable working fluid. Other possible working fluids that may be circulated through the vapor compression system 330 include R-123, R-514A, R-1224yd, R-1233zd, R-134a, R-1234ze, R-1234yf, R-1311, and R-32. In some embodiments, the vapor compression system 330 may be configured to efficiently utilize a working fluid having a normal boiling point of about 19 degrees Celsius (66 degrees Fahrenheit or less) at one atmosphere of pressure, also referred to as low pressure working fluids, versus a medium pressure working fluids, such as R-134a. As used herein, “normal boiling point” may refer to a boiling point temperature measured at one atmosphere of pressure.

The vapor compression system 330 may further include a control panel 344 (e.g., a controller) that has an analog to digital (A/D) converter 346, a microprocessor 348, a non-volatile memory 350, and/or an interface board 352. In some embodiments, the vapor compression system 330 may use one or more of a variable speed drive (VSDs) 354 and a motor 356. The motor 356 may drive the compressor 336 and may be powered by the VSD 354. The VSD 354 receives alternating current (AC) power having a particular fixed line voltage and fixed line frequency from an AC power source and provides power having a variable voltage and frequency to the motor 356. In other embodiments, the motor 356 may be powered directly from an AC or direct current (DC) power source. The motor 356 may include any type of electric motor that can be powered by the VSD 354 or directly from an AC or DC power source, such as a switched reluctance motor, an induction motor, an electronically commutated permanent magnet motor, or another suitable motor.

The compressor 336 may be configured to pressurize and/or compress a working fluid vapor received from the electronic equipment 301 and may direct the working fluid vapor along the working fluid circuit 334 toward the condenser 338. In certain embodiments, the working fluid vapor may be delivered from the compressor 336 to an oil separator 358 configured to separate oil from the working fluid vapor. In such embodiments, the working fluid vapor is then directed toward the condenser 338, and the oil is returned to the compressor 336. In other embodiments, the compressor 336 may be an oil-less compressor (e.g., magnetic bearing compressor), and the working fluid vapor is delivered from the compressor 336 to the condenser 338 (e.g., without passing through an oil separator, such as the oil separator 358). In such embodiments, the oil-less compressor 336 may include one or more components that form a portion of the working fluid circuit and are configured to enable pressurization of the working fluid while mitigating exposure of the working fluid to potential particulates or contaminants within the compressor 336.

For example, in certain cases, it may be desirable to mitigate exposure of the working fluid directed toward the electronic equipment 301 to potential particulates or contaminants. Indeed, exposure of the working fluid to certain materials, such as materials that may be susceptible to corrosion and/or degradation (e.g., chemical or electrochemical corrosion), may cause particulates, contaminants, or other impurities to mix with (e.g., become entrained within) the working fluid before the working fluid is delivered to the electronic equipment 301. Introduction of a fluid (e.g., working fluid) having particulates, contaminants, or other impurities mixed therein may cause wear and/or degradation to the electronic equipment 301, and in some cases, may cause operational disruptions of the electronic equipment 301. To this end, the compressor 336 may include one or more bearings 337 (e.g., magnetic bearings, primary bearings, secondary bearings, mechanical bearings) configured to limit an amount of metal-to-metal contact (e.g., metal-to-metal skidding) within the compressor 336, thereby reducing potential creation of particulates, contaminants, or impurities within the compressor that may otherwise be created via metal-to-metal contact, as discussed in greater detail below. In this way, the working fluid directed through the compressor 336 may remain free or substantially free of particulates, contaminants, or other impurities, such that the working fluid may be suitable for placing in a heat transfer arrangement with electronic equipment 301.

The working fluid vapor delivered to the condenser 338 may transfer heat to a cooling fluid at the condenser 338. For example, the cooling fluid may be ambient air 360 forced across heat exchanger coils of the condenser 338 by condenser fans 362. The working fluid vapor may condense to a working fluid liquid in the condenser 338 as a result of thermal heat transfer with the cooling fluid (e.g., the ambient air 360). The liquid working fluid exits the condenser 338 and then flows through a first expansion device 364 (e.g., the expansion device 340, an electronic expansion valve). The first expansion device 364 may be a flash tank feed valve configured to control flow of the liquid working fluid to the flash tank 332. The first expansion device 364 is also configured to lower the pressure of (e.g., expand) the liquid working fluid received from the condenser 338. During the expansion process, a portion of the liquid may vaporize, and thus, the flash tank 332 may be used to separate the vapor from the liquid received from the first expansion device 364. Additionally, the flash tank 332 may provide for further expansion of the liquid working fluid due to a pressure drop experienced by the liquid working fluid when entering the flash tank 332 (e.g., due to a rapid increase in volume experienced when entering the flash tank 332).

The vapor in the flash tank 332 may exit and flow to the compressor 336. For example, the vapor may be drawn to an intermediate stage of the compressor 336 (e.g., not the suction stage). A valve 366 (e.g., an economizer valve, solenoid valve) may be included in the working fluid circuit 334 to control flow of the working fluid vapor from the flash tank 332 to the compressor 336. In some embodiments, when the valve 366 is open (e.g., fully open), additional liquid working fluid within the flash tank 332 may vaporize and provide additional subcooling of the liquid working fluid within the flash tank 332. The liquid working fluid that collects in the flash tank 332 may be at a lower enthalpy than the liquid working fluid exiting the condenser 338 due to the expansion in the first expansion device 364 and/or the flash tank 332. The liquid working fluid may flow from the flash tank 332, through a second expansion device 368 (e.g., the expansion device 340, an orifice), and to the electronic equipment 301 (e.g., via the portion 335 of the working fluid circuit 334 that extends to and from the electronic equipment 301). In some embodiments, the working fluid circuit 334 may also include a valve 370 (e.g., a drain valve) configured to regulate flow of liquid working fluid from the flash tank 332 to the electronic equipment 301. For example, the valve 370 may be controlled (e.g., via the control panel 344) based on an amount of suction superheat of the working fluid.

The liquid working fluid delivered to the electronic equipment 301 may absorb heat from the computer components 303 disposed within and/or thermally coupled to the computer enclosure 302, such that the liquid working fluid directed to the electronic equipment 301 may undergo a phase change to become working fluid vapor. For example, the working fluid circuit 334 may be configured to circulate the working fluid along the portion 335 from the flash tank 332 to the electronic equipment 301 and from the electronic equipment 301 to the compressor 336 (e.g., without an intermediate stage of heat exchange, such as via an evaporator and/or a CDU heat exchanger), thereby enabling cooling of the electronic equipment 301 via the working fluid. Said another way, the portion 335 of the working fluid circuit 334 may extend directly to the electronic equipment 301 (e.g., one or more components of the computer equipment 301) without any intervening heat exchange components. For example, while the portion 335 may include certain valves, sensors, filters, pumps, and/or other fluid conveyance devices, the portion 335 of working fluid circuit 334 may not include a heat exchanger, such as a CDU heat exchanger, configured to exchange heat between a conditioning fluid circulated between the CDU and an evaporator and a coolant circulated between the CDU and the electronic equipment. Additionally, the working fluid circuit 334 may not include an evaporator configured to exchange heat between a working fluid circulated along the working fluid circuit and a conditioning fluid (e.g., water) circulated between the evaporator and the electronic equipment. Thus, by extending at least the portion 335 of the working fluid circuit 334 to the electronic equipment 301, one or more stages of heat exchange and/or heat transfer included in certain systems, such as systems having a CDU heat exchanger and/or multiple coolant loops, may be omitted, which may enable operation of the computer cooling system 300 which reduced energy consumption.

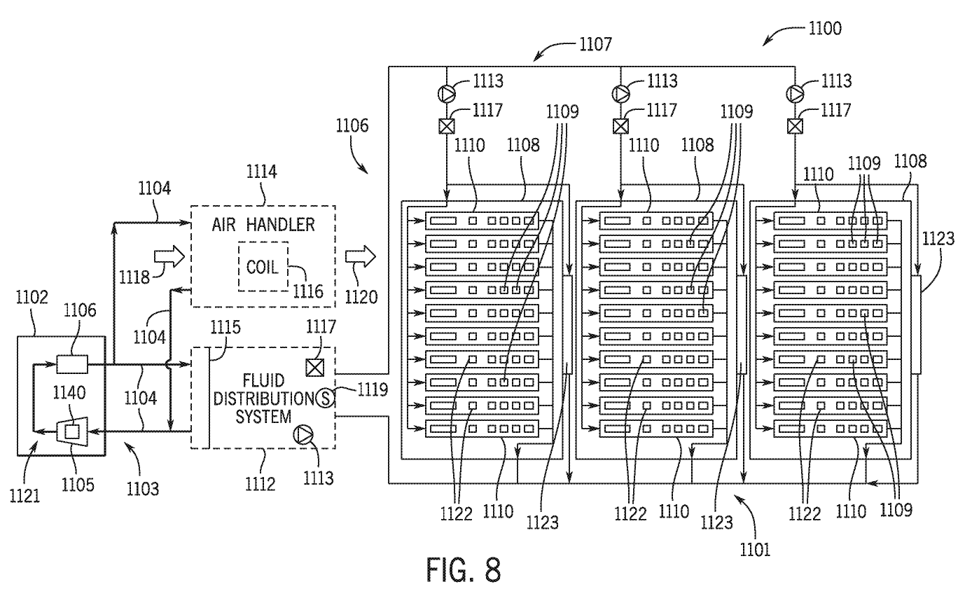

FIG. 8 is a schematic of an embodiment of a cooling system 1100 (e.g., computer cooling system, electronic equipment cooling system, data center cooling system, cooling system 300) configured to provide cooling to electronic equipment 1101. The cooling system 1100 includes a chiller system 1102 (e.g., vapor compression system 330, HVAC&R system) configured to generate (e.g., cool) a working fluid 1104 (e.g., cooling fluid, two-phase fluid) that is directed to the electronic equipment 1101 (e.g., electronic equipment 301) to cool the electronic equipment 1101. In some embodiments, the chiller system 1102 may be an air-cooled chiller. For example, the chiller system 1102 may operate in a manner similar to that described above with respect to the vapor compression system 330, and may include a working fluid circuit 1103 (e.g., working fluid circuit 334) having a compressor system 1105 (e.g., compressor 336) and one or more condensers 1106 (e.g., condenser 338, condenser coils, heat exchangers), among other components (e.g., expansion valve(s), flash tank, motor, VSD, etc.). In certain embodiments, the compressor system 1105 may circulate the working fluid 1104 along the working fluid circuit 1103 (e.g., along a portion 1107 of the working fluid circuit 1103) to the electronic equipment 1101 to place the working fluid 1104 in a heat exchange relationship with the electronic equipment 1101. The working fluid 1104 may absorb heat from the electronic equipment 1101 (e.g., cool the electronic equipment 1101) and may be delivered back to the compressor system 1105. In an embodiment of the chiller system 1102 configured as an air-cooled chiller, the condenser(s) 1106 may enable transfer of heat from the working fluid 1104 to ambient air, thereby cooling the working fluid 1104 and enabling rejection of heat absorbed by the working fluid 1104 from the electronic equipment 1101. However, it should be appreciated that the chiller system 1102 may include other configurations and/or components, such as a water-cooled chiller, a cooling tower, a dry cooler, another suitable component or system, or any combination thereof. In some embodiments, the cooling system 1100 may include an air handler 1114 (e.g., air handling unit) having a heat exchanger 1116 (e.g., coil) configured to receive the working fluid 1104 to cool an air flow 1118 directed across the heat exchanger 1116 to generate a cooled air flow 1120. The cooled air flow 1120 may be directed to the electronic equipment 1101 to cool the electronic equipment 1101.

In the illustrated embodiment, the electronic equipment 1101 includes a plurality of cabinets 1108 (e.g., racks 102, server cabinet, computer cabinet, electronics cabinet), and each cabinet 1108 is configured to support a respective plurality of computer enclosures 1110 (e.g., computer enclosure 302). Each computer enclosure 1110 is configured to contain, house, and/or support one or more computer components 1109 (e.g., computer componentry 303), such as one or more server trays (e.g., server trays 104), computer chips, integrated circuits, circuit boards, communication circuitry, processors, servers, memories, routers, switches, controllers, heat-generating components (e.g., heat-generating components 164), and/or other computer hardware. In some embodiments, one or more of the cabinets 1108 may be a computer server rack, a computer equipment rack, a server rack, a server chassis, or other suitable structure configured to support one or more of the computer enclosures 1110. The computer enclosures 1110 may include a rack server enclosure, a server tray enclosure, a blade server enclosure, another suitable enclosure configured to contain electronic components, or any combination thereof. The cabinets 1108 may be disposed within an embodiment of a building configured as a data center.

During operation, the electronic equipment 1101 may generate heat, which may cause a temperature of the computer components 1109 within and/or thermally coupled to the computer enclosures 1110 to increase. It is desirable to maintain the temperature of the computer components 1109 disposed within and/or thermally coupled to the computer enclosures 1110 below applicable temperature thresholds in order to enable proper operation of the computer components 1109 and avoid operational interruptions. Accordingly, present embodiments include the cooling system 1100 configured to supply the working fluid 1104 to the cabinets 1108 and/or the computer enclosures 1110 to absorb heat generated by the computer components 1109 and reject the heat to another suitable location or environment.

As will be appreciated, some systems utilized to cool computer components may include an HVAC&R system having a working fluid circuit, a conditioning fluid circuit configured to circulate a conditioning fluid, and a coolant circuit configured to circulate a coolant. During operation of such systems, the working fluid circuit (e.g., refrigeration circuit 111) and the conditioning fluid circuit (e.g., primary coolant loop 120) may be in a heat exchange relationship to enable transfer of heat from the conditioning fluid to the working fluid, while the conditioning fluid circuit and the coolant circuit (e.g., secondary coolant loop 130) may be in a heat exchange relationship to enable transfer of heat from the coolant fluid to the conditioning fluid. For example, such systems may include a coolant distribution unit (CDU) (e.g., CDU 106) having a heat exchanger configured to establish a heat exchange relationship between the conditioning fluid circuit and the coolant circuit. The coolant circuit may extend from the CDU to the computer equipment to place the coolant in a heat exchange relationship with the computer equipment in order to absorb heat generated by the computer equipment.

Various embodiments of the cooling system 1100 do not include a CDU having a heat exchanger configured to place a conditioning fluid and a coolant in a heat exchange relationship. Present embodiments also may not include a separate coolant circuit and/or conditioning fluid circuit in addition to the working fluid circuit 1103 of the chiller system 1102. Further still, present embodiments also may not include an evaporator positioned along the working fluid circuit 1103. Instead, the cooling system 1100 is configured to circulate the working fluid 1104 along the working fluid circuit 1103 between aspects of the chiller system 1102 (e.g., the compressor system 1105 and/or the compressors 1106 of the chiller system 1102) and the electronic equipment 1101 (e.g., cabinets 1108, computer enclosures 1110). Thus, the working fluid circuit 1103 may place the working fluid 1104 in a heat exchange relationship with the computer components 1109 disposed within and/or thermally coupled to the computer enclosures 1110. For example, the working fluid circuit 1103 may include one or more flow paths that extend within the cabinets 1108 and/or within one or more of the computer enclosures 1110. In certain embodiments, the working fluid 1104 may be circulated through the computer enclosure 1110, such as via a tube, conduit, flow path, channel, vessel, chilled plate, cold plate, immersion cooling techniques (e.g., direct contact with one or more computer components 1109), or any combination thereof. In this way, one or more stages of heat transfer typically included in certain systems may be omitted, which may enable operation of the chiller system 1102 with reduced energy consumption.

In some embodiments, the cooling system 1100 (e.g., the working fluid circuit 1103) may also include a fluid distribution system 1112 configured to enable distribution of the working fluid 1104 to the electronic equipment 1101 (e.g., to each cabinet 1108, to each computer enclosure 1110). The working fluid circuit 1103 and/or the fluid distribution system 1112 may include one or more components, such as one or more pumps 1113, filters 1115, valves 1117, sensors 1119, bypass conduits, and so forth that enable selective distribution of the working fluid 1104 to the electronic equipment 1101. For example, the fluid distribution system 1112 may include one or more sensors 1119 configured to detect a parameter indicative of a quality or characteristic of the working fluid 1104 (e.g., particle concentration, chemical component) directed to the cabinets 1108 and/or computer enclosures 1110. In some embodiments, the fluid distribution system 1112 may include an in-line spectrometry sensor disposed along the working fluid circuit 1103. The fluid distribution system 1112 may include certain components associated with a respective one of the cabinets 1108. For example, the fluid distribution system 1112 may include multiple pumps 1113 and/or valves 1117 configured to service (e.g., regulate flow of the working fluid 1104) to one or more of the cabinets 1108 and/or computer enclosures 1110. In certain embodiments, each cabinet 1108 and/or computer enclosure 1110 may be associated with a corresponding pump 1113 and/or valve 1117. Further, in certain embodiments, one or more of the valves 1117 may correspond to an expansion device (e.g., expansion device 368) configured to decrease the pressure of the working fluid 1104 before delivering the working fluid 1104 to the electronic equipment 1101. As will be appreciated, the cooling system 1100 may include any number of pumps 1113 and/or valves 1117 to enable selective distribution of the working fluid 1104 to the electronic equipment 1101 (e.g., to each of the cabinets 1108 and/or computer enclosures 1110). In this way, components of the fluid distribution system 1112 (e.g., pumps 1113, valves 1117) may be actuated to suspend flow of the working fluid 1104 to one of the cabinets 1108 and/or computer enclosures 1110, while enabling flow of the working fluid 1104 to remaining cabinets 1108 and/or computer enclosures 1110. In some embodiments, the fluid distribution system 1112 may be configured to regulate flow of a respective portion of the working fluid 1104 to each computer enclosure 1110 disposed within the cabinet 1108 (e.g., via corresponding valves 1117 associated with each computer enclosure 1110).

In some embodiments, the fluid distribution system 1112 may include one or more filters 1115 (e.g., permeable membrane) configured to enable flow of the working fluid 1104 therethrough and to capture one or more particles and/or contaminants within the flow of working fluid 1104. One or more of the components of the fluid distribution system 1112 may be contained in a dedicated housing or unit, distributed along the working fluid circuit 1103 at other locations, integrated within one or more of the cabinets 1108, integrated with the chiller system 1102, or any combination thereof.

In certain embodiments, the portion 1107 of the working fluid circuit 1103 that extends to the electronic equipment 1101 (e.g., extends through one or more of the cabinets 1108) may be defined by any suitable component disposed within and/or thermally coupled to the cabinet 1108. Said another way, the portion 1107 of the working fluid circuit 1103 may be at least partially defined by one or more of the cabinets 1108, one or more of the computer enclosures 1110, a heat exchanger 1122 (e.g., cold plate) coupled to or disposed within one or more of the computer enclosures 1110, a heat exchanger 1123 (e.g., rear door heat exchanger) disposed within the cabinet 1108, or any combination thereof. For example, as discussed in greater detail below, a heat exchange interface between the working fluid 1104 and the computer component 1109 may take any of various forms, including direct immersion of the computer component 1109 in the working fluid 1104, direct and/or thermal contact between the computer component 1109 and a cold plate 1122 configured to receive the working fluid 1104, or the like.

For example, in certain embodiments, the computer component 1109 may be positioned within an interior volume (e.g., pressure vessel) defined by the computer enclosure 1110. The interior volume of the computer enclosure 1110 may correspond to a pressure vessel configured to receive the working fluid 1104, such that the computer component 1109 disposed therein is immersed in the working fluid 1104 and cooled via immersion cooling techniques. In other embodiments, the computer enclosure 1110 may include the cold plate 1122 (e.g., cold plate, chilled plate) disposed within the interior volume and operable to receive the working fluid 1104. The cold plate 1122 may be engaged with (e.g., thermally coupled to) the computer component 1109 to facilitate heat exchange between the working fluid 1104 and the computer component 1109. In still other embodiments, the computer component 1109 may be positioned external to the computer enclosure 1110 and may be thermally coupled to the cold plate 1122 to enable heat exchange between the working fluid 1104 and the computer component 1109. In any case, the computer component 1109 may be placed in a heat exchange relationship with the working fluid 1104 of the chiller system 1102, thereby enabling the working fluid 1104 to absorb heat from (e.g., cool) the computer component 1109.

Additionally, or alternatively, one or more of the cabinets 1108 may include the heat exchanger 1123. The heat exchanger 1123 may be configured to transfer heat from within the cabinet 1108 (e.g., heat generated by the electronic equipment 1101 within the cabinet 1108) to the working fluid 1104 directed through the heat exchanger 1123. For example, in certain embodiments, air (e.g., ambient air) may be directed through and/or across the electronic equipment 1101 (e.g., computer enclosures 1110 and/or computer components 1109) to absorb heat from the electronic equipment 1101. In embodiments in which the heat exchanger 1123 is configured as a rear door heat exchanger, the heat exchanger 1123 may be positioned within a respective cabinet 1108 supporting the electronic equipment 1101 downstream of the electronic equipment 1101 (e.g., relative to a flow direction of the air flow across the electronic equipment 1101). The heat exchanger 1123 may circulate the working fluid 1104 therethrough, thereby enabling the air flow to transfer heat to the working fluid 1104. In any case, the portion 1107 of the working fluid circuit 1103 may enable transfer of heat from within the cabinet 1108 (e.g., transfer of heat generated by the computer components 1109 within the cabinet 1108) to the working fluid 1104 directed along the working fluid circuit 1103. After absorbing heat from the electronic equipment 1101, the working fluid 1104 may be directed along an additional portion 1121 of the working fluid circuit 1103 defined at least in part by the compressor system 1105 and the condensers 1106, thereby enabling rejection of the heat and cooling of the working fluid 1104 (e.g., via thermal heat transfer with a cooling fluid, such as ambient air, directed across the condensers 1106).

Present embodiments may also include a cooling system (e.g., computer cooling system, data center cooling system) configured to operate in various operating modes (e.g., a mechanical cooling mode, a free cooling mode, hybrid cooling mode) to satisfy cooling demands associated with the electronic equipment. For example, in certain systems, free cooling operations may be activated during certain conditions, such as when ambient temperature is relatively low (e.g., in the spring, winter, and/or fall seasons). When the ambient temperature is relatively low, a cooling demand of the computer cooling system may be reduced and/or operating conditions may enable the computer cooling system to operate at an adequate cooling capacity without powering the compressor.

To this end, present embodiments may include a computer cooling system having a vapor compression system (e.g., mechanical cooling system, chiller system, air-cooled chiller system) and a free cooling system (e.g., free cooling circuit). The computer cooling system may facilitate modes of operation (e.g., mechanical cooling mode, free cooling mode, hybrid cooling mode) that employ different aspects of the computer cooling system to achieve more efficient cooling of computer components (e.g., electronic equipment). For example, the vapor compression system may include a working fluid circuit having a compressor, a condenser, a directional valve, and an accumulator. During operation of the computer cooling system in a mechanical cooling mode, working fluid from the condenser may be directed through the directional valve and through an expansion valve and toward electronic equipment (e.g., toward a heat exchanger or heat exchange interface in thermal communication with the electronic equipment) to absorb heat from the electronic equipment. For example, at least a portion of the working fluid circuit may extend through the electronic equipment to enable the working fluid to absorb heat from (e.g., to cool) the electronic equipment, such as via a chilled plate, a cold plate, a tube, a flow path, a channel, a vessel, and/or immersion cooling techniques. After absorbing heat from the electronic equipment, the working fluid may be directed to the accumulator, which may retain some amount of liquid working fluid therein while enabling gaseous working fluid to flow to the compressor.

When free cooling operations are enabled, components of the working fluid circuit may enable heat transfer between the working fluid and other fluids (e.g., water, cooling fluid) passing through the free cooling system (e.g., while suspending operation of one or more components of the vapor compression system, such as the compressor). In the free cooling mode, the directional valve may block flow of the working fluid from the condenser, and instead, may direct flow of working fluid from the accumulator via a pump. For example, condensed working fluid within the accumulator may be drawn by the pump and directed along another portion of the working fluid circuit that extends through the directional valve, the expansion valve, and the electronic equipment, thereby enabling the working fluid to absorb heat from (e.g., cool) the electronic equipment. A free cooling circuit of the free cooling system may extend through the accumulator and may be configured to cool the working fluid within the accumulator (e.g., during the free cooling mode). For example, the free cooling circuit may be configured to circulate a cooling fluid (e.g., water, glycol, free cooling fluid) and establish, via a heat exchange interface, a heat exchange relationship between the cooling fluid and the working fluid.

In certain cases, the heat exchange interface may include one or more tubes extending through the accumulator (e.g., extending through a portion, such as a bottom portion, of the accumulator that includes condensed liquid working fluid). For example, the accumulator may be configured to receive working fluid from the electronic equipment after the working fluid has absorbed heat from the electronic equipment. The accumulator may define an interior volume configured to receive the working fluid from the electronic equipment (e.g., receive the working fluid circulated along the working fluid circuit). The one or more tubes of the heat exchange interface may extend through the interior volume of the accumulator, such that as cooling fluid is circulated along the free cooling circuit and through the one or more tubes, the cooling fluid may absorb heat from the working fluid directed across the tubes. The working fluid, having been cooled and condensed by the cooling fluid directed through the tubes, may be drawn by the pump and directed along the working fluid circuit to absorb additional heat from the electronic equipment. The free cooling circuit may also include one or more free cooling coils configured to place the cooling fluid in a heat exchange relationship with another fluid (e.g., ambient air) to enable cooling of the cooling fluid after the cooling fluid absorbs heat from the working fluid via the heat exchange interface within the accumulator.

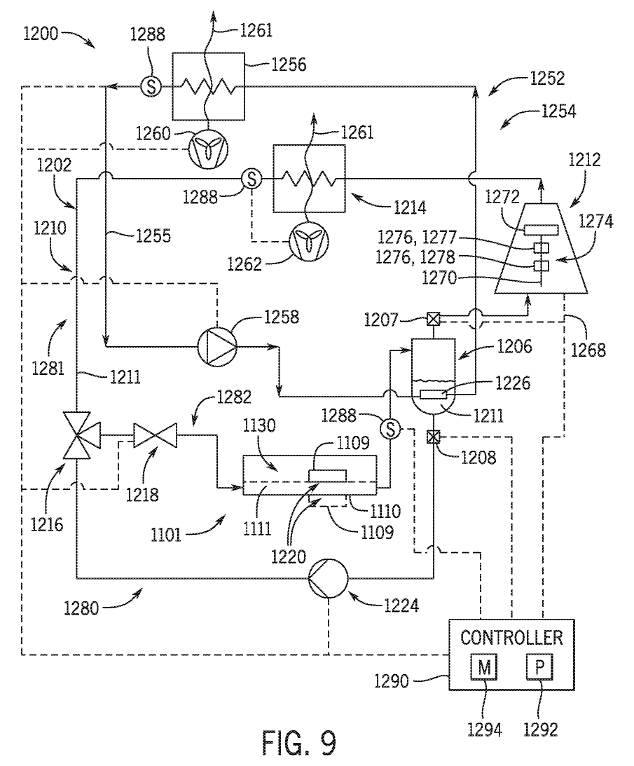

With the preceding in mind, FIG. 9 is a schematic diagram of an embodiment of a cooling system 1200 (e.g., computer cooling system 1100, computer cooling system 300, data center cooling system 100) including a vapor compression system 1202 (e.g., mechanical cooling system, chiller system 1102) and a free cooling system 1252 (e.g., free cooling circuit). The vapor compression system 1202 and the free cooling system 1252 may be referred to as a combined mechanical and free cooling system and/or an integrated mechanical and free cooling system. The cooling system 1200 may facilitate modes of operation (e.g., a mechanical cooling mode and a free cooling mode) that employ different aspects of the cooling system 1200 to achieve more efficient cooling of the electronic equipment 1101, which is generally represented by a computer component 1109 disposed within a computer enclosure 1110. The illustrated embodiment depicts fluid flow circuits and heat exchange relationships that may take any of various physical forms. For example, the schematic diagram of FIG. 9 depicts generic heat exchange between a working fluid flow (e.g., a refrigerant flow, flow of the working fluid 1104) and the computer component 1109. Present embodiments may achieve this heat exchange via any of various component arrangements, as discussed in greater detail below. As will be appreciated, the cooling system 1200 may be configured to provide a working fluid flow to any suitable number of computer enclosures 1110 disposed within any number of cabinets 1108, thereby enabling the cooling system 1200 to provide cooling to the corresponding computer components 1109 disposed therein and/or thermally coupled thereto, as discussed in greater detail below.

The vapor compression system 1202 may operate in a manner similar to that described above with respect to the vapor compression system 330 and/or the chiller system 1102. For example, the vapor compression system 1202 includes a working fluid circuit 1210 (e.g., vapor compression circuit, working fluid circuit 1103) configured to circulate a working fluid 1211, such as a refrigerant, therethrough via a compressor 1212 (e.g., compressor 336, compressor system 1105) disposed along the working fluid circuit 1210. The working fluid circuit 1210 also includes a condenser 1214 (e.g., condenser 338, condenser 1106, air-cooled condenser, condenser coil, heat exchanger coil), and the working fluid circuit 1210 is configured to direct the working fluid 1211 from the condenser 1214 to a directional valve 1216 (e.g., a three-way valve) that facilitates control of flow direction of the working fluid 1211 through the cooling system 1200. During operation of the cooling system 1200 in a mechanical cooling mode, the directional valve 1216 directs working fluid 1211 from the condenser 1214 to an expansion valve 1218, which causes the working fluid to expand and, as a result, drop substantially in temperature. Thereafter, the working fluid 1211 is directed, via the working fluid circuit 1210, toward the electronic equipment 1101, which is generally represented by an embodiment of the computer component 1109 disposed within an embodiment of the computer enclosure 1110, to exchange (e.g., absorb) heat generated by the computer component 1109. As mentioned above, a heat exchange interface 1220 between the working fluid 1211 and the computer component 1109 may take any of various forms, including direct immersion of the computer component 1109 in the working fluid 1211, direct and/or thermal contact between the component 1109 and a chilled plate or cold plate configured to receive the working fluid 1211, and so forth.

For example, as mentioned above, in certain embodiments the computer component 1109 may be positioned within an interior volume 1130 (e.g., pressure vessel) defined by the computer enclosure 1110. The interior volume 1130 of the computer enclosure 1110 may correspond to a pressure vessel configured to receive the working fluid 1211 (e.g., liquid working fluid), such that the computer component 1109 disposed therein is immersed in the liquid working fluid and cooled via immersion cooling techniques. In other embodiments, the computer enclosure 1110 may include the heat exchanger 1122 (e.g., cold plate, chilled plate) disposed within the interior volume 1130 and operable to receive the working fluid 1211. The heat exchanger 1122 may be engaged with (e.g., thermally coupled to) the computer component 1109 to facilitate heat exchange between the working fluid 1211 and the computer component 1109. In still other embodiments, the computer component 1109 may be positioned external to the computer enclosure 1110 and may be thermally coupled to the heat exchanger 1122 to enable heat exchange between the working fluid 1211 and the computer component 1109. For example, in certain embodiments, the computer enclosure 1110 may correspond to a frame or enclosure configured to support one or more heat exchangers 1122 (e.g., cold plates). In such embodiments, an additional support structure, such as a server tray having one or more computer components 1109 disposed thereon, may be mounted to the computer enclosure 1110 such that the one or more computer components 1109 engage with (e.g., thermally engage with) the one or more heat exchangers 1122 supported by the computer enclosure 1110. In any case, the computer component 1109 may be placed in a heat exchange relationship with the working fluid 1211 of the vapor compression system 1202 via the heat exchange interface 1220, thereby enabling the working fluid 1211 to absorb heat from (e.g., cool) the computer component 1109.

At least a portion of the working fluid 1211 may flash (e.g., vaporize) upon exchanging heat with the computer component 1109 via the heat exchange interface 1220, and the working fluid 1211 may be directed into an accumulator 1206 of the vapor compression system 1202. The accumulator 1206 may be configured to retain some amount of liquid working fluid while enabling vaporized working fluid to flow to the compressor 1212 of the vapor compression system 1202, such as during a mechanical cooling mode of the cooling system 1200. For example, in certain cases, vaporized working fluid 1211 returning from the electronic equipment 1101 may include droplets of liquid working fluid entrained therein. The accumulator 1206 may be configured to receive the working fluid 1211 (e.g., two-phase working fluid mixture) and separate the vaporized working fluid from the liquid working fluid. In certain embodiments, the accumulator 1206 may include one or more valves, such as a first valve 1207 and a second valve 1208 configured to regulate the flow of the working fluid 1211 out of the accumulator 1206 (e.g., based on an operating mode of the cooling system 1100). For example, during a mechanical cooling mode of the cooling system 1100, the valve 1207 may be controlled (e.g., via a controller) to enable vaporized working fluid within the accumulator 1206 to flow to the compressor 1212, while the valve 1208 may be controlled (e.g., closed) to suspend flow of liquid working fluid out of the accumulator 1206. During the mechanical cooling mode, the compressor 1212 may pressurize the working fluid 1211 before directing the working fluid 1211 along the working fluid circuit 1210 to the condenser 1214 to enable rejection of the heat absorbed by the electronic equipment 1101.

During operation of the cooling system 1200 in a free cooling mode, the components of the working fluid circuit 1210 may enable heat transfer between the working fluid 1211 (e.g., refrigerant) and other fluids (e.g., water) passing through the free cooling system 1252 while suspending operation of one or more components of the vapor compression system 1202 (e.g., compressor 1212). In the free cooling mode of operation, the directional valve 1216 may be controlled to block flow from the condenser 1214 to the expansion valve 1218 and direct (e.g., enable) flow from a pump 1224, which may be activated in the free cooling mode, through the expansion valve 1218. In the mechanical cooling mode, the directional valve 1216 may be controlled to block flow from the pump 1224 to the expansion valve 1218 and/or flow from the directional valve 1216 to the pump 1224. Accordingly, switching from the mechanical cooling mode to the free cooling mode may include reversing the operation (e.g., position) of the directional valve 1216. With the pump 1224 operational in the free cooling mode, the valve 1208 may be controlled (e.g., opened) to enable liquid working fluid within the accumulator 1206 to be drawn by the pump 1224 from the accumulator 1206 and directed to the directional valve 1216, which is configured to direct the working fluid 1211 through the expansion valve 1218. The working fluid 1211 (e.g., refrigerant) passing through the expansion valve 1218 drops in pressure and correspondingly drops in temperature to facilitate more efficient heat exchange when the working fluid 1211 contacts or otherwise exchanges heat with the computer component 1109. At least some portion of the working fluid 1211 will flash (e.g., vaporize) and return in a gaseous, blended, and/or mixed (e.g., two-phase) phase state to the accumulator 1206, as described above.

As previously noted, components of the working fluid circuit 1210 may enable heat transfer between the working fluid 1211 (e.g., refrigerant) and other fluids (e.g., water) passing through the free cooling system 1252. Specifically, a free cooling circuit 1254 of the free cooling system 1252 may be configured to circulate a cooling fluid 1255 (e.g., water, glycol, free cooling fluid) and establish a heat exchange relationship, as depicted by heat exchange interface 1226, between the cooling fluid 1255 and the working fluid 1211 (e.g., between the free cooling system 1252 and the vapor compression system 1202). The heat exchange interface 1226 may be any suitable arrangement of one or more components configured to enable transfer of heat between the working fluid 1211 circulated along the working fluid circuit 1210 and the cooling fluid 1255 (e.g., free cooling fluid) circulated through the free cooling system 1252 (e.g., free cooling circuit 1254). For example, as discussed in greater detail below, the heat exchange interface 1226 may include and/or may be defined at least in part by one or more tubes, shells, enclosures, manifolds, pipes, conduits, plates, flow channels, flow paths, another suitable component, or any combination thereof of the vapor compression system 1202 and/or the free cooling system 1252. In some embodiments, the heat exchange interface 1226 may include a heat exchanger, such as a brazed plate heat exchanger and/or shell and tube heat exchanger, whereby certain portions of the heat exchanger are defined by aspects of the vapor compression system 1202 (e.g., the accumulator 1206) while other portions of the heat exchanger are defined by aspects of the free cooling system 1252. Indeed, it should be appreciated that the heat exchange interface 1226 may take any of various forms that enable transfer of heat between the working fluid 1211 and the cooling fluid 1255 (e.g., free cooling fluid), as discussed in greater detail below.

As an example, the accumulator 1206 may include or define a shell, vessel, or other container having an internal volume configured to receive the working fluid 1211 circulated along the working fluid circuit 1210 (e.g., working fluid returning from the electronic equipment 1101), and the heat exchange interface 1226 may be defined at least in part by one or more flow paths, channels, and/or tubes (e.g., of the free cooling circuit 1254) extending through the interior volume of the accumulator 1206 (e.g., through a bottom or lower portion of the shell of the accumulator 1206, through a shell and tube separator portion of the accumulator 1206). The cooling fluid 1255 circulated through the one or more flow paths, channels, and/or tubes may be fluidly separated from the working fluid 1211 within the vessel, and the one or more flow paths, channels, and/or tubes may enable transfer of heat from the working fluid 1211 within the vessel to the cooling fluid 1255 within the flow paths, channels, and/or tubes. In this way, the cooling fluid 1255 may cool the working fluid 1211.

As mentioned above, the working fluid 1211 (e.g., gaseous working fluid, two-phase working fluid) may be directed from the electronic equipment 1101 (e.g., from the heat exchange interface 1220) to the accumulator 1206, such as to an upper portion of the accumulator 1206. In the free cooling mode, heat is transferred from the working fluid 1211 within the accumulator 1206 to the cooling fluid 1255 circulated through the flow paths, channels, and/or tubes of the free cooling circuit 1254 extending through the accumulator 1206 (e.g., through a shell and tube separator portion of the accumulator 1206). At least some of the gaseous working fluid within the accumulator 1206 (e.g., vaporized via heat exchange with the computer component 1109) may therefore condense and collect at a bottom of the accumulator 1206. In some embodiments, the flow paths, channels, and/or tubes disposed along the free cooling circuit 1254 that at least partially define the heat exchange interface 1226 may be disposed within a lower portion of the accumulator 1206. Thus, condensed working fluid accumulating and/or collecting at the lower or bottom portion of the accumulator 1206 may be further cooled by the cooling fluid 1155 directed through the flow paths, channels, and/or tubes. The liquid working fluid at the bottom of the accumulator 1206 may be drawn out of the accumulator 1206 and through the valve 1208 via operation of the pump 1224 to be circulated along a portion 1280 of the working fluid circuit 1210. The pump 1224 may circulate the liquid working fluid to the directional valve 1216 and the expansion valve 1218 to enable flow of the liquid working fluid to the computer component 1109, as described above. In certain embodiments, the portion 1280 of the working fluid circuit 1210 that extends from the accumulator 1206, through the pump 1224 and to the directional valve 1216 may correspond to a free cooling portion 1280 of the working fluid circuit 1210, while a portion 1281 of the working fluid circuit 1210 that extends from the accumulator 1206, through the compressor 1212, through the condenser 1214, and to the directional valve 1216 may correspond to a mechanical cooling portion 1281 of the working fluid circuit 1210. A portion 1282 of the working fluid circuit 1210 that extends from the directional valve 1216, through the expansion valve 1218, through the electronic equipment 1101, and to the accumulator 1206 may correspond to a heat exchange portion 1282 of the working fluid circuit 1210. In certain embodiments, each of the free cooling portion 1280 and the mechanical cooling portion 1281 may be defined at least in part by the heat exchange portion 1282 of the working fluid circuit 1210.

The free cooling system 1252 also includes one or more free cooling coils 1256 (e.g., free cooling heat exchanger) disposed along the free cooling circuit 1254. The free cooling circuit 1254 is configured to direct the cooling fluid 1255 from the heat exchange interface 1226 to the free cooling coil 1256. For example, the free cooling system 1252 may include a pump 1258 (e.g., liquid pump, free cooling pump) disposed along the free cooling circuit 1254 and configured to force flow of the cooling fluid 1255 along the free cooling circuit 1254. The free cooling coil 1256 is configured to place the cooling fluid 1255 in a heat exchange relationship with another fluid to enable cooling of the cooling fluid 1255 after the cooling fluid 1255 absorbs heat from the working fluid 1211 via the heat exchange interface 1226. For example, the free cooling coil 1256 is configured to place the cooling fluid 1255 in a heat exchange relationship with air 1261 (e.g., ambient air, a first flow of ambient air) directed across the free cooling coil 1256 via one or more fans 1260 (e.g., one or more free cooling fans, one or more first fans).

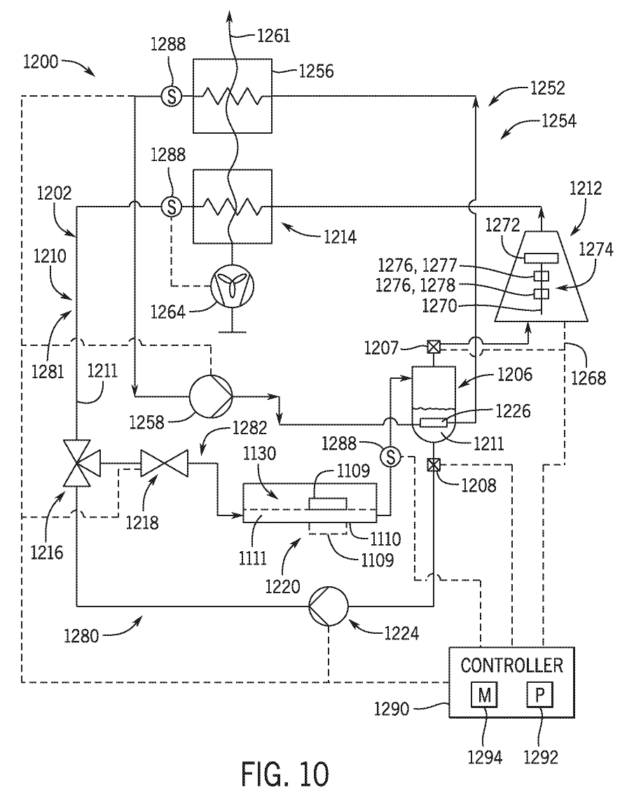

In the illustrated embodiment, the cooling system 1200 (e.g., vapor compression system 1202) also includes a fan 1262 (e.g., second fan, condenser fan) configured to force air 1261 (e.g., ambient air, a second flow of ambient air) across the condenser 1214 during operation of the cooling system 1200 in the mechanical cooling mode (e.g., during operation of the vapor compression system 1202). As shown in FIG. 9, the condenser 1214 and the free cooling coil 1256 are arranged separately (e.g., staggered, offset, relative to flows of air directed across the condenser 1214 and the free cooling coil 1256) and are configured to receive separate flows (e.g., two different flows) of air 1261 via the fan 1262 and the fan 1260, respectively. However, in other embodiments, the condenser 1214 and the free cooling coil 1256 may be arranged in a different manner. For example, as depicted in FIG. 10, the condenser 1214 and the free cooling coil 1256 may be configured in a stacked arrangement (e.g., nested arrangement), and the cooling system 1200 may include a common fan 1264 (e.g., one or more fans) configured to force a flow of air 1261 (e.g., ambient air) across both the condenser 1214 and the free cooling coil 1256. In some embodiments, the free cooling coil 1256 may be disposed downstream of the condenser 1206 relative to a flow direction of air 1261 directed across the free cooling coil 1256 and the condenser 1206 via the common fan 1264. It should be appreciated that other arrangements of the condenser 1214 and the free cooling coil 1256 may also be implemented in accordance with the present techniques.

As shown in FIGS. 9 and 10, the compressor 1212 may include a housing 1268 and a shaft 1270 extending through the housing 1268, where the shaft 1270 is coupled to an impeller 1272 of the compressor 1212 (e.g., via a fastener). During operation of the compressor 1212, such as during a mechanical cooling mode of the cooling system 1200, the shaft 1270 may rotate (e.g., via operation of a motor) and cause rotation of the impeller 1272 within the housing 1268. Rotation of the impeller 1272 may drive the working fluid 1211 along the working fluid circuit 1210, as described above. As mentioned above, in certain embodiments, it may be desirable to mitigate exposure of the working fluid 1211 directed to the electronic equipment 1101 to potential particulates or contaminants. To this end, the compressor 1212 may be an oil-less compressor and may include a bearing system 1274 configured to limit or reduce an amount of metal-to-metal contact (e.g., metal-to-metal skidding) in the compressor 1212 while supporting and enabling rotation of the shaft 1270, and thus, the impeller 1272 of the compressor 1212.

The bearing system 1274 may include bearings 1276 (e.g., bearing assemblies, primary bearing assemblies, magnetic bearing assemblies, backup bearing assemblies, ball bearing assemblies) disposed circumferentially about the shaft 1270. In certain embodiments, one or more of the bearings 1276 may correspond to primary bearings 1277 (e.g., magnetic bearings) configured to control (e.g., actively control) and/or adjust a position of the shaft 1270, whereas other bearings 1276 may correspond to backup bearings 1278 configured to support and enable rotation of the shaft 1270, such as during instances in which operation of the primary bearings 1277 is inadvertently (e.g., unexpectedly) interrupted and/or otherwise adversely impacted. In certain embodiments, each of the primary bearings 1277 may include a magnetic bearing configured to impart forces (e.g., magnetic forces) onto the shaft 1270 to enable desired positioning and/or support of the shaft 1270 during operation of the compressor 1212. In some embodiments, one or more of the primary bearings 1277 may be active magnetic bearings having actuators, controllers, coils, and/or other features configured to continuously and/or continually receive and/or adjust a current supplied to the primary bearings to adjust and/or maintain a position of the shaft 1270 during rotation. For example, the primary bearings 1277 may include thrust bearings, axial bearings, radial bearings, magnetic radial bearings, and/or magnetic thrust bearings configured to control, adjust, and/or enable desired positioning (e.g., axial positioning, radial positioning) and rotation of the shaft 1270 during operation of the compressor 1212. Specifically, the primary bearings 1277 are configured to support a load (e.g., axial load, radial load) on the shaft 1270 via imparting magnetic forces onto the shaft 1270 to cause the shaft 1270 to levitate within the primary bearings 1277.

As mentioned above, the backup bearings 1278 may be configured to support and enable rotation of the shaft 1270, such as during instances in which operation of the primary bearings 1277 is inadvertently interrupted. The backup bearings 1278 may be configured to reduce, limit, or mitigate an amount of metal-to-metal contact within the compressor 1212, thereby limiting an amount of particulates, contaminants, or impurities that may otherwise be generated based on metal-to-metal contact within the compressor 1212. For example, at least a portion (e.g., a shaft contacting surface) of each of the backup bearings 1278 that is configured to contact the shaft 1270 (e.g., when operation of the primary bearings 1277 is inadvertently interrupted) may include or be formed from a non-conductive material, such as ceramic, silicon nitride, or zirconium dioxide, thereby limiting metal-to-metal contact within the compressor 1212.

Referring to FIGS. 9 and 10, in certain embodiments, the cooling system 1200 may include one or more sensors 1288 (e.g., sensors 1119) configured to detect various operating parameters and/or operating conditions of the cooling system 1200. The one or more sensors 1288 may be disposed throughout the cooling system 1200 (e.g., along the working fluid circuit 1210, along the portion of the working fluid circuit 1280, within and/or proximate to the computer enclosure 1110, within and/or proximate the compressor 1212, the condenser 1214, and/or the accumulator 1206) and may be configured to detect data indicative of a quality or characteristic (e.g., particle concentration, chemical component, temperature, pressure) of the working fluid 1211 and/or the cooling fluid 1255, data indicative of a quality or characteristic of the air 1261, another suitable parameter, or any combination thereof. For example, in certain embodiments, the sensors 1288 may provide data indicative of a leaving fluid temperature of the working fluid directed through the computer enclosure 1110, and the leaving fluid temperature may be indicative of a cooling demand associated with the computer component 1109 disposed within and/or thermally coupled to the computer enclosure 1110. As another example, the sensors 1288 may be configured to monitor or detect a quality or characteristic (e.g., temperature, humidity) of the air flow 1261 (e.g., of the ambient air surrounding the cooling system 1200). Based on a temperature of the air 1261 being above a threshold value, the cooling system 1200 may be operated in a mechanical cooling mode, whereas temperatures below the threshold value may enable operation of the cooling system 1200 in the free cooling mode.

The one or more sensors 1288 may be communicatively coupled to a control system 1290 (e.g., controller, automation controller), thereby enabling the control system 1290 to control operation of the cooling system 1100 and/or various components thereof (e.g., compressor 1212, condenser 1214, directional valve 1216, expansion valve 1218, accumulator 1206, valves 1207 and 1208, pumps 1224 and 1258, free cooling coil 1256, fans 1260, 1262, 1264) based on data received from the one or more sensors 1288 and/or in accordance with the present techniques. In certain embodiments, the control system 1290 may be configured to determine whether and/or how to operate the vapor compression system 1202 and/or the free cooling system 1252 based on a temperature of the air flow 1261 (e.g., temperature of the ambient air in a surrounding environment of the cooling system 1200) and/or a cooling load demand (e.g., an amount of cooling demanded by a load, such as the electronic equipment 1101). Said another way, the control system 1290 may be configured to transition operation of the computer cooling system 1100 between a free cooling mode and a mechanical cooling mode based on the temperature of the ambient air and/or a cooling load demand associated with the electronic equipment 1101.

As an example, upon determining (e.g., in response to a determination) that the temperature of the air flow 1261 is above a threshold value or temperature (e.g., based on data from the sensors 1288) and/or that a cooling demand is above a threshold value, the control system 1290 may be configured to operate the cooling system 1100 in the mechanical cooling mode. In the mechanical cooling mode, the control system 1290 may control a position of the valve 1207 (e.g., open the valve 1207) to enable vaporized working fluid from the accumulator 1206 to flow to the compressor 1212. The control system 1290 may also control a position of the valve 1208 (e.g., close the valve 1208) to block working fluid (e.g., liquid working fluid, condensed working fluid) within the accumulator 1206 from flowing along the portion 1280 of the working fluid circuit 1210. In certain embodiments, the control system 1290 may additionally or alternatively control operation of the compressor 1212 (e.g., by driving rotation of the shaft 1270 via a motor and/or VSD, by controlling operation of the bearing system 1274, such that the primary bearings 1277 levitate the shaft 1270 and enable desired positioning and rotation of the shaft 1270) to pressurize and direct the vaporized working fluid received from the accumulator 1206 to the condenser 1214. Further, in the mechanical cooling mode, the control system 1290 may operate the fans 1262, 1264 to direct the air 1261 across the condenser 1214 to reject heat from the working fluid 1211, thereby condensing the working fluid 1211. As will be appreciated, the control system 1290 may also control the positioning of the directional valve 1216 to enable flow of the condensed working fluid from the condenser 1214 to the expansion valve 1218 (e.g., enable flow along the mechanical cooling portion 1281 of the working fluid circuit 1210) and from the expansion valve 1218 to the electronic equipment 1101 while blocking flow of condensed working fluid from the portion 1280 of the working fluid circuit 1210 (e.g., free cooling portion 1280 extending from the accumulator 1206 to the directional valve 1216).

Upon determining (e.g., in response to a determination) that the temperature of the air flow 1261 is below the threshold value or temperature (e.g., based on data from the sensors 1288), the control system 1290 may determine to operate the cooling system 1200 in the free cooling mode. In the free cooling mode, the control system 1290 may control a position of the valve 1208 (e.g., open the valve 1208) to enable working fluid (e.g., condensed working fluid, liquid working fluid) within the accumulator 1206 to flow out of the accumulator 1206 and along the portion 1280 of the working fluid circuit 1210. The control system 1290 may also control a position of the valve 1207 (e.g., close the valve 1207) to block vaporized working fluid within the accumulator 1206 from flowing toward the compressor 1212. Further, in some embodiments, the control system 1290 may suspend operation of the compressor 1212 and initiate operation of the pumps 1224, 1258. Upon initiating operation of the pump 1224 (e.g., via the control system 1290), working fluid within the accumulator 1206 may be drawn by the pump 1224 and directed along the portion 1280 of the working fluid circuit 1210 to the directional valve 1216. In the free cooling mode, the control system 1290 may control the positioning of the directional valve 1216 to enable flow of the working fluid from the portion 1280 of the working fluid circuit 1210 to the expansion valve 1218 and from the expansion valve 1218 to the electronic equipment while blocking flow of condensed working fluid from the condenser 1214 (e.g., blocking flow along the mechanical cooling portion 1281). Additionally, upon initiating operation of the pump 1258 (e.g., via the control system 1290), free cooling fluid 1255 may be directed along the free cooling circuit 1254 and through the heat exchange interface 1226. As mentioned above, the cooling fluid 1255 may be circulated through the heat exchange interface 1226 (e.g., via one or more tubes, conduits, flow paths, etc.) to absorb heat from the working fluid 1211 within the accumulator 1206, thereby cooling and/or condensing the working fluid 1211. After absorbing heat from the working fluid 1211 within the accumulator 1206, the cooling fluid 1255 may be directed toward the free cooling coils 1256, and the control system 1290 may operate the fans 1260, 1264 to reject heat away from the cooling fluid 1255.

In certain embodiments, the control system 1290 may include processing circuitry 1292 (e.g., processor system, one or more microprocessors) and a memory 1294 (e.g., one or more memory devices). For example, the controller 1290 may include non-transitory code or instructions stored on a machine-readable medium (e.g., memory 1294) and that may be executed by the processing circuitry 1292 to implement the techniques disclosed herein. The memory 1294 may include volatile memory, such as read-only memory (ROM), optical drives, hard disc drives, solid-state drives, or any other non-transitory, computer-readable medium storing instructions that, when executed by the processing circuitry 1292, control operation of the vapor compression system 1202, the free cooling system 1252, and/or aspects thereof, to provide cooling to the electronic equipment 1101, in accordance with one or more of the techniques described herein.

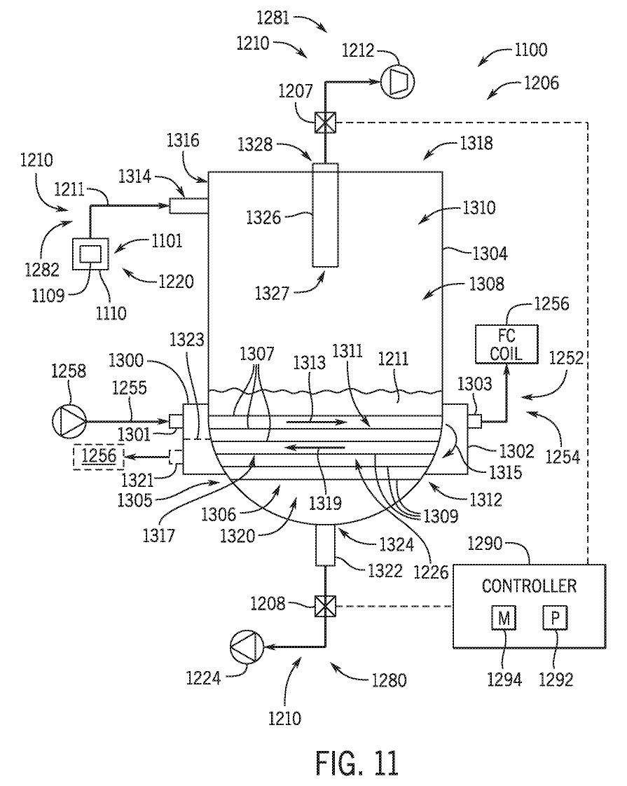

FIG. 11 is a cross-sectional schematic view of an embodiment of an accumulator, such as the accumulator 1206, that may be included in the cooling system 1200. As discussed above, the accumulator 1206 may be configured to enable the cooling system 1200 to transition between a mechanical cooling mode and a free cooling mode by receiving the working fluid 1211 from the electronic equipment 1101 and directing (e.g., selectively directing) the working fluid 1211 along either the mechanical cooling portion 1281 or the free cooling portion 1280 of the working fluid circuit 1210 based on current operating conditions (e.g., based on a temperature of the ambient air, based on a cooling demand associated with the electronic equipment 1101). Further, in certain embodiments, the accumulator 1206 may include components and/or features that at least partially define the heat exchange interface 1226 between the cooling fluid 1255 and the working fluid 1211 (e.g., between the free cooling system 1252 and the vapor compression system 1202). Said another way, the heat exchange interface 1226 may be at least partially integrated within (e.g., disposed within, disposed internal to) the accumulator 1206, thereby enabling the accumulator 1206 to facilitate heat exchange between the cooling fluid 1255 and the working fluid 1211 (e.g., when free cooling operations are enabled).

In the illustrated embodiment, the accumulator 1206 includes a first water box 1300 (e.g., first manifold, first fluid manifold) configured to receive the cooling fluid 1255 (e.g., from the free cooling circuit 1254 via an inlet 1301 of the first water box 1300) and a second water box 1302 (e.g., second manifold, second fluid manifold) configured to discharge the cooling fluid 1255 (e.g., toward the free cooling coil 1256 via an outlet 1303 of the second water box 1302) after the cooling fluid 1255 has absorbed heat from the working fluid 1211 within the accumulator 1206. The first water box 1300 and the second water box 1302 may be secured (e.g., coupled, mounted, attached, welded) to a shell 1304 (e.g., housing) of the accumulator 1206. As shown in the illustrated embodiment, a plurality of tubes 1306 (e.g., flow paths, channels) may be disposed within an interior volume 1308 defined by the shell 1304. In certain embodiments, the interior volume 1308 may further be divided into an upper portion or section 1310 (e.g., vapor working fluid portion, separation portion) and a lower portion or section 1312 (e.g., condensed working fluid portion, condensing portion, bottom portion), and the plurality of tubes 1306 (e.g., the heat exchanger 1305) may be disposed within the lower portion 1312.

The plurality of tubes 1306 may extend from the first water box 1300 to the second water box 1302 to collectively define a heat exchanger 1305 of the free cooling system 1252. For example, in certain embodiments, the heat exchanger 1305 and/or the plurality of tubes 1306 may be arranged as a single-pass heat exchanger. In such embodiments, the cooling fluid 1255 may flow into the first water box 1300 (e.g., via the inlet 1301), through the plurality of tubes 1306, into the second water box 1302, and out of the second water box 1302 via the outlet 1303. Thus, the first water box 1300 may be configured to distribute the cooling fluid 1255 to the plurality of tubes 1306.

In other embodiments, the heat exchanger 1305 and/or the plurality of tubes 1306 may be arranged as a multi-pass heat exchanger, whereby the plurality of tubes 1306 are divided into tube bundles that define one or more passes through the shell 1304. For example, the plurality of tubes 1306 may be divided into a first subset of tubes 1307 and a second subset of tubes 1309, where each subset of tubes 1307, 1309 is associated with a separate pass of the heat exchanger 1305. In such embodiments, the cooling fluid 1255 is directed from piping of the free cooling circuit 1254 into the first water box 1300 via the inlet 1301. The cooling fluid 1255 is then directed from the first water box 1300 to the first subset 1307 of the plurality of tubes 1306, such that the cooling fluid 1255 flows through a first pass 1311 of the heat exchanger 1305, as indicated by arrow 1313. The cooling fluid 1255 exits the first subset 1307 of the plurality of tubes 1306 and enters the second water box 1302, which may be configured to direct and/or redirect the cooling fluid 1255 to the second subset 1309 of the plurality of tubes 1306, as indicated by arrow 1315 (e.g., in embodiments in which the heat exchanger 1305 is arranged as a multi-pass heat exchanger).

After being re-directed by the second water box 1302, as indicated by the arrow 1315, the cooling fluid 1255 may be directed from the second water box 1302 to the second subset 1309 of the plurality of tubes 1306, such that the cooling fluid 1255 flows through a second pass 1317 of the heat exchanger 1305, as indicated by arrow 1319. After the cooling fluid 1255 exits the second subset 1309 of the plurality of tubes 1306, the cooling fluid 1255 may flow into the first water box 1300 and may exit the first water box 1300 via an outlet 1321 of the first water box 1300 (e.g., as shown in phantom lines). To this end, in certain embodiments (e.g., embodiments in which the heat exchanger 1305 is arranged as a multi-pass heat exchanger), the first water box 1300 may include a partition plate 1323 (e.g., separation plate) configured to separate the cooling fluid 1255 flowing through the first water box 1300 from the inlet 1301 to the first subset 1307 of the plurality of tubes 1306 (e.g., cooling fluid 1255 entering the first pass 1311) and the cooling fluid 1255 flowing through the first water box 1300 from the second subset 1309 of the plurality of tubes 1306 to the outlet 1321 of the first water box 1300 (e.g., cooling fluid 1255 exiting the second pass 1317).

In certain embodiments, the heat exchange interface 1226 may be defined at least in part by the plurality of tubes 1306. For example, as mentioned above, during operation of the cooling system 1100 in the free cooling mode, the pump 1258 may be operated (e.g., via the control system 1290) to direct the cooling fluid 1255 toward the heat exchange interface 1226 and through the plurality of tubes 1306. As the cooling fluid 1255 is directed through the tubes 1306, working fluid 1211 returning from the electronic equipment 1101 (e.g., working fluid 1211 that has absorbed heat from the electronic equipment 1101) may be directed into the shell 1304 (e.g., into the upper portion 1310 of the shell 1304) via an inlet 1314 (e.g., working fluid inlet) positioned along a side 1316 of the shell 1304. In certain embodiments, the inlet 1314 may be positioned proximate (e.g., less than a threshold distance away from) a top or roof 1318 of the shell 1304. The working fluid 1211 entering the accumulator 1206, having just absorbed heat from the electronic equipment 1101, may transfer the heat to the cooling fluid 1255 directed through the plurality of tubes 1306 (e.g., during the free cooling mode). As the heat is transferred from the working fluid 1211 to the cooling fluid 1255, at least a portion of the working fluid 1211 within the accumulator 1206 will condense and fall toward the lower portion 1312 of the shell 1304. In certain embodiments, the condensed working fluid 1211 may accumulate within a basin or reservoir portion 1320 of the shell 1304. Further, in certain embodiments, one or more of the plurality of tubes 1306 (e.g., at least a portion of the heat exchanger 1305) may extend through the basin or reservoir portion 1320 to enable additional cooling of the working fluid 1211 within the basin or reservoir portion 1320. As heat is transferred from the working fluid 1211 to the cooling fluid 1255 (e.g., during the free cooling mode), the cooling fluid 1255 may be directed out of the shell 1304 (e.g., via the pump 1258) and toward the free cooling coil 1256, thereby enabling rejection of the heat absorbed by the cooling fluid 1255 from the working fluid 1211.

During the free cooling mode, working fluid 1211 that has condensed (e.g., via heat exchange with the cooling fluid 1255 directed through the tubes 1306) and collected within the basin or reservoir portion 1320 may exit the shell 1304 via an outlet 1322 (e.g., first outlet, liquid outlet) positioned at a bottom 1324 of the shell 1304. For example, the outlet 1322 may be fluidly coupled to the valve 1208 and to the pump 1224. As discussed above, when free cooling operations are enabled, the valve 1208 may be controlled (e.g., via the control system 1290) to transition toward an open position and the pump 1224 may be operated (e.g., via the control system 1290) to draw the liquid working fluid out of the shell 1304 (e.g., from the reservoir portion 1320) via the outlet 1322, through the valve 1208, and along the portion 1280 of the working fluid circuit 1210 toward the directional valve 1216.

As mentioned above, during operation of the cooling system 1200 in the mechanical cooling mode, operation of the pumps 1224, 1258 may be suspended, the valve 1208 may be closed, and the valve 1207 may be opened (e.g., via the control system 1290) to enable flow of vaporized working fluid within the upper portion 1310 of the shell 1304 to flow along the working fluid circuit 1210 toward the compressor 1212 (e.g., to flow along the mechanical cooling portion 1281 of the working fluid circuit 1210). For example, during operation of the cooling system 1200 in the mechanical cooling mode, working fluid 1211 may be delivered into the shell 1304 via the inlet 1314, as described above. In certain embodiments, the accumulator 1206 (e.g., the shell 1304) may be configured to decrease a velocity of the working fluid 1211 directed into the accumulator 1206, thereby enabling liquid droplets within the working fluid 1211 to fall (e.g., via gravity) toward the bottom portion 1312 of the shell 1304. By separating liquid droplets from gaseous working fluid, the accumulator 1206 may enable vaporized working fluid having substantially no liquid entrained therein to be directed to the compressor 1212.

For example, the accumulator 1206 may include a conduit 1326 (e.g., gas outlet conduit, vapor outlet) extending at least partially through and/or into the interior volume 1308 and configured to receive (e.g., collect, direct) vaporized working fluid that is substantially free of liquid working fluid from within the interior volume 1308 of the accumulator 1206. The vaporized working fluid may then be directed from the conduit 1326 to the compressor 1212. In certain embodiments, the conduit 1326 may include one or more openings 1327 (e.g., inlet) and/or orifices (e.g., metering orifices) that enable vaporized working fluid to be collected and/or directed (e.g., discharged) from the upper portion 1310 of the shell 1304 while redirecting liquid working fluid toward the lower portion 1312 of the shell 1304. In certain embodiments, the conduit 1326 may extend through the top or roof 1318 of the shell 1304 into the interior volume 1308. In any case, the conduit 1326 may include an outlet 1328 fluidly coupling the conduit 1326 to the compressor 1212 (e.g., via the valve 1207), thereby enabling delivery of vaporized working fluid to the compressor 1212, such as during a mechanical operating mode of the cooling system 1100. It should be appreciated that the techniques disclosed herein may be utilized with accumulators having other configurations, and thus, the working fluid may enter and exit the shell of the accumulator at locations along the shell other than those shown in FIG. 11.

As set forth above, the present disclosure may provide one or more technical effects useful in operating computer cooling systems that circulate working fluid to cool electronic equipment. For example, embodiments of the present disclosure may include a chiller system that operates to cool a working fluid and circulate the working fluid between the chiller system and the electronic equipment. Said another way, at least a portion of the working fluid circuit may extend through the electronic equipment, such that certain embodiments discussed herein do not include and/or incorporate a CDU heat exchanger and/or an evaporator configured to enable heat transfer between two flows of fluid. Therefore, one or more stages of heat transfer and/or heat exchange included in some computer cooling systems is omitted, thereby enabling enhanced efficiency of the chiller system and increased heat rejection of heat generated by the electronic equipment.

Moreover, embodiments of the present disclosure may include a chiller system (e.g., data center cooling system, computer cooling system, electronics cooling system) having a vapor compression system and a free cooling system (e.g., integrated mechanical and free cooling system), thereby enabling a computer cooling system to operate in various modes (e.g., mechanical cooling mode, free cooling mode) to satisfy cooling demands associated with the electronic equipment. For example, the vapor compression system may include a working fluid circuit having a first portion (e.g., mechanical cooling portion) that extends from an accumulator, through a compressor, through a condenser, through a directional valve, through the electronic equipment, and back to the accumulator. The working fluid circuit may also include a second portion (e.g., free cooling portion) that extends from the accumulator, through a pump, through the directional valve, through the electronic equipment, and back to the accumulator. The accumulator may be configured to enable transition between the mechanical cooling mode and the free cooling mode by receiving working fluid from the electronic equipment and selectively directing the working fluid along either the mechanical cooling portion or the free cooling portion of the working fluid circuit based on one or more operating conditions (e.g., sensor feedback, one or more detected operating conditions) of the data center cooling system and/or computer cooling system (e.g., based on a temperature of the ambient air, based on a cooling demand associated with the electronic equipment).

Additionally, the accumulator may at least partially define a heat exchange interface, such as one or more tubes extending through an interior volume of the accumulator, that enables the free cooling system to cool and condense the working fluid within the accumulator (e.g., when free cooling operations are enabled and/or activated). By integrating the heat exchange interface within the accumulator, computer cooling systems discussed herein may include a reduced number of separate heat exchange components, thereby providing a simplified system architecture and reducing potential points of failure. Furthermore, the free cooling operations enabled by the present techniques may significantly reduce energy consumption by suspending operation of the compressor during periods in which ambient temperature conditions permit cooling of the working fluid via the free cooling circuit.

While only certain features and embodiments have been illustrated and described, many modifications and changes may occur to those skilled in the art, such as variations in sizes, dimensions, structures, shapes and proportions of the various elements, values of parameters, such as temperatures and pressures, mounting arrangements, use of materials, colors, orientations, and so forth, without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

1. A computer cooling system, comprising:
a mechanical cooling system comprising a working fluid circuit configured to circulate a working fluid;
a free cooling system comprising a free cooling circuit configured to circulate a cooling fluid;
a first heat exchange interface disposed along the working fluid circuit, wherein the first heat exchange interface is configured to place the working fluid in a first heat exchange relationship with a computer component; and
an accumulator disposed along the working fluid circuit and configured to receive the working fluid from the first heat exchange interface, wherein the accumulator at least partially defines a second heat exchange interface configured to place the working fluid in a second heat exchange relationship with the cooling fluid.

2. The computer cooling system of claim 1, wherein the accumulator comprises a shell defining an interior volume, the free cooling circuit comprises at least one flow path extending through the interior volume of the shell, and the at least one flow path is configured to circulate the cooling fluid therethrough to place the cooling fluid in the second heat exchange relationship with the working fluid.

3. The computer cooling system of claim 2, wherein the accumulator is configured to separate the working fluid into liquid working fluid and vapor working fluid, the shell comprises an upper portion and a lower portion, the lower portion defines a reservoir configured to collect the liquid working fluid, and the at least one flow path extends through the lower portion and at least partially through the reservoir.

4. The computer cooling system of claim 3, wherein the accumulator comprises a conduit extending at least partially into the upper portion of the shell, the conduit comprises one or more openings configured to receive the vapor working fluid, and the conduit is configured to direct the vapor working fluid to a compressor positioned along the working fluid circuit.

5. The computer cooling system of claim 2, wherein the at least one flow path comprises a tube, and the accumulator comprises:
a first water box secured to the shell;
a second water box secured to the shell; and
a plurality of tubes including the tube extending from the first water box to the second water box and through the interior volume of the shell.

6. The computer cooling system of claim 1, wherein the mechanical cooling system comprises a compressor disposed along the working fluid circuit and configured to circulate the working fluid along the working fluid circuit, wherein the compressor comprises at least one magnetic bearing configured to support a shaft of the compressor.

7. The computer cooling system of claim 1, wherein the mechanical cooling system comprises a condenser disposed along the working fluid circuit, the free cooling system comprises a free cooling coil disposed along the free cooling circuit, the condenser and the free cooling coil are arranged in a stacked arrangement, and the computer cooling system comprises a common fan configured to force ambient air across the condenser and the free cooling coil.

8. The computer cooling system of claim 1, wherein the mechanical cooling system comprises a condenser disposed along the working fluid circuit, the free cooling system comprises a free cooling coil disposed along the free cooling circuit, the condenser and the free cooling coil are arranged separate from one another, and the computer cooling system comprises a first fan configured to force a first flow of ambient air across the free cooling and a second fan configured to force a second flow of ambient air across the free cooling coil.

9. A computer cooling system, comprising:
a mechanical cooling system comprising a working fluid circuit configured to circulate a working fluid, a compressor disposed along the working fluid circuit, and a first pump disposed along the working fluid circuit;
a free cooling system comprising a free cooling circuit and a second pump disposed along the free cooling circuit, wherein the second pump is configured to circulate a cooling fluid along the free cooling circuit;
a heat exchange interface disposed along the working fluid circuit, wherein the heat exchange interface is configured to place the working fluid in a heat exchange relationship with a computer component;
an accumulator disposed along the working fluid circuit, wherein the accumulator is configured to separate the working fluid into liquid working fluid and vapor working fluid; and
a control system configured to:
drive operation of the compressor to draw the vapor working fluid from the accumulator in a mechanical cooling mode of the computer cooling system; and
suspend operation of the compressor and initiate operation of the first pump to draw the liquid working fluid from the accumulator in a free cooling mode of the computer cooling system.

10. The computer cooling system of claim 9, comprising one or more sensors configured to collect data indicative of a temperature of an ambient environment surrounding at least a portion of the computer cooling system, wherein the control system is configured to transition operation of the computer cooling system between the free cooling mode and the mechanical cooling mode based on the temperature of the ambient environment.

11. The computer cooling system of claim 10, wherein the control system is configured to:
operate the computer cooling system in the free cooling mode based on the data indicating that the temperature is below a threshold temperature; and
operate the computer cooling system in the mechanical cooling mode based on the data indicating that the temperature is above the threshold temperature.

12. The computer cooling system of claim 9, comprising a directional valve disposed along the working fluid circuit, wherein the control system is configured to:
control the directional valve to enable flow of the working fluid from a condenser of the mechanical cooling system toward the heat exchange interface and to block flow of the working fluid from the accumulator toward the heat exchange interface in the mechanical cooling mode; and
control the directional valve to enable flow of the working fluid from the accumulator toward the heat exchange interface and to block flow of the working fluid from the condenser toward the heat exchange interface in the free cooling mode.

13. The computer cooling system of claim 12, comprising an expansion valve positioned along the working fluid circuit between the directional valve and the heat exchange interface, wherein the expansion valve is configured to decrease a pressure of the working fluid and direct the working fluid toward the heat exchange interface.

14. The computer cooling system of claim 12, wherein the working fluid circuit comprises a first valve disposed between the accumulator and the compressor and a second valve disposed between the accumulator and the directional valve, and wherein the control system is configured to:
control the first valve to enable the vapor working fluid within the accumulator to flow to the compressor in the mechanical cooling mode; and
control the second valve to enable the liquid working fluid within the accumulator to flow to the directional valve in the free cooling mode.

15. The computer cooling system of claim 9, wherein, in the free cooling mode, the control system is configured to operate the second pump of the free cooling system to circulate the cooling fluid through at least one tube extending through the accumulator to cool the working fluid within the accumulator.

16. The computer cooling system of claim 9, comprising the computer component, wherein the computer component is disposed within an interior volume of a computer enclosure, the interior volume at least partially defines the heat exchange interface, and the computer enclosure is configured to receive the working fluid into the interior volume to cool the computer component via immersion cooling.

17. The computer cooling system of claim 9, comprising the computer component, wherein the computer component is disposed within an interior volume of a computer enclosure, and the heat exchange interface comprises a cold plate disposed within the interior volume and thermally coupled to the computer component.

18. An accumulator for a computer cooling system configured to operate in a mechanical cooling mode and a free cooling mode, wherein the accumulator comprises:
a shell defining an interior volume configured to receive a working fluid from a heat exchange interface of the computer cooling system in both the mechanical cooling mode and the free cooling mode, wherein the shell comprises an upper portion and a lower portion, the accumulator is configured to separate the working fluid into vapor working fluid and liquid working fluid, and the lower portion defines a reservoir configured to collect the liquid working fluid;
at least one flow channel extending through the interior volume of the shell, wherein the at least one flow channel is disposed along a free cooling circuit and is configured to circulate a cooling fluid therethrough during the free cooling mode to place the cooling fluid in a heat exchange relationship with the working fluid within the accumulator;
a first outlet disposed at a bottom of the shell and configured to enable the liquid working fluid to exit the shell during the free cooling mode via a pump disposed along a free cooling portion of a working fluid circuit; and
a conduit extending at least partially through the upper portion of the shell, wherein the conduit comprises one or more openings configured to receive the vapor working fluid from within the shell and a second outlet configured to direct the vapor working fluid along a mechanical cooling portion of the working fluid circuit to a compressor of the computer cooling system during the mechanical cooling mode.

19. The accumulator of claim 18, comprising:
a first valve fluidly coupled to the second outlet and configured to:
enable flow of the vapor working fluid along the mechanical cooling portion of the working fluid circuit during the mechanical cooling mode; and
block flow of the vapor working fluid along the mechanical cooling portion of the working fluid circuit during the free cooling mode; and
a second valve fluidly coupled to the first outlet and configured to:
enable flow of the liquid working fluid along the free cooling portion of the working fluid circuit during the free cooling mode; and
block flow of the liquid working fluid along the free cooling portion of the working fluid circuit during the mechanical cooling mode.

20. The accumulator of claim 18, wherein the at least one flow channel comprises a tube, and wherein the accumulator comprises a first water box coupled to the shell, a second water box coupled to the shell, and a plurality of tubes including the tube, wherein the plurality of tubes extends from the first water box to the second water box and
defines multiple passes for the cooling fluid circulated therethrough during the free cooling mode.
